(19) United States
(12) Patent Application Publication
(10) Pub. No.: US 2026/0170209 A1
(43) Pub. Date: Jun. 18, 2026

(54) DESIGN METHOD, PROGRAM, AND SEMICONDUCTOR MEMORY DEVICE

(71) Applicant: Kioxia Corporation, Tokyo (JP)

(72) Inventor: Hirotsugu KAWASHIMA, Inabe Mie (JP)

(73) Assignee: Kioxia Corporation, Tokyo (JP)

(21) Appl. No.: 19/234,371

(22) Filed: Jun. 11, 2025

(30) Foreign Application Priority Data
Dec. 17, 2024 (JP) 2024-220743

(51) Int. Cl. G06F 30/32; H10B 43/27

(52) U.S. Cl. CPC G06F 30/32; H10B 43/27

(57) ABSTRACT

A design method according to one embodiment is a design method of determining an arrangement of a plurality of holes having different reaching depths, the design method including: calculating, in a case in which a resin layer covering the plurality of holes having a first arrangement is formed, a first layer thickness difference in the resin layer on the plurality of holes; determining whether the first layer thickness difference is equal to or less than a predetermined upper limit value; calculating, when the first layer thickness difference exceeds the upper limit value, a second layer thickness difference generated in the resin layer on the plurality of holes in a case in which the arrangement of the plurality of holes is changed to a second arrangement; and determining whether the second layer thickness difference is equal to or less than the upper limit value.

### CROSS-REFERENCE TO RELATED APPLICATIONS

This application is based upon and claims the benefit of priority from Japanese Patent Application No. 2024-220743, filed on Dec. 17, 2024; the entire contents of which are incorporated herein by reference.

### FIELD

Embodiments described herein relate generally to a design method, a program, and a semiconductor memory device.

### BACKGROUND

In a semiconductor memory device such as a three-dimensional nonvolatile memory, a plurality of conductive layers are stacked on each other, and a plurality of contacts connected to the respective conductive layers at different depth positions are formed. Such a contact is obtained by repeating formation of a resist pattern and formation of a contact hole having a different reaching depth a plurality of times. When the resist pattern is repeatedly formed on a plurality of contact holes having different reaching depths, layer thickness control of the resist pattern becomes a problem.

### BRIEF DESCRIPTION OF THE DRAWINGS

FIGS. 1A and 1B are schematic diagrams each illustrating a schematic configuration example of a semiconductor memory device according to a first embodiment;

FIGS. 2A and 2B are cross-sectional views each illustrating an example of a configuration of the semiconductor memory device according to the first embodiment;

FIGS. 3A to 3C are diagrams sequentially illustrating a part of a procedure of a manufacturing method of the semiconductor memory device according to the first embodiment;

FIGS. 4A and 4B are diagrams sequentially illustrating a part of the procedure of the manufacturing method of the semiconductor memory device according to the first embodiment;

FIGS. 5A and 5B are diagrams sequentially illustrating a part of the procedure of the manufacturing method of the semiconductor memory device according to the first embodiment;

FIGS. 6A and 6B are diagrams sequentially illustrating a part of the procedure of the manufacturing method of the semiconductor memory device according to the first embodiment;

FIGS. 7A to 7D are diagrams sequentially illustrating a part of the procedure of the manufacturing method of the semiconductor memory device according to the first embodiment;

FIGS. 8A to 8C are diagrams sequentially illustrating a part of the procedure of the manufacturing method of the semiconductor memory device according to the first embodiment;

FIGS. 9A to 9C are diagrams sequentially illustrating a part of the procedure of the manufacturing method of the semiconductor memory device according to the first embodiment;

FIGS. 10A to 10C are diagrams sequentially illustrating a part of the procedure of the manufacturing method of the semiconductor memory device according to the first embodiment;

FIGS. 11A and 11B are diagrams sequentially illustrating a part of the procedure of the manufacturing method of the semiconductor memory device according to the first embodiment;

FIGS. 12A and 12B are diagrams sequentially illustrating a part of the procedure of the manufacturing method of the semiconductor memory device according to the first embodiment;

FIGS. 13A and 13B are diagrams sequentially illustrating a part of the procedure of the manufacturing method of the semiconductor memory device according to the first embodiment;

FIGS. 14A and 14B are diagrams sequentially illustrating a part of the procedure of the manufacturing method of the semiconductor memory device according to the first embodiment;

FIGS. 15A and 15B are diagrams sequentially illustrating a part of the procedure of the manufacturing method of the semiconductor memory device according to the first embodiment;

FIGS. 16A and 16B are cross-sectional views each illustrating an example of an arrangement order of contact holes according to a comparative example;

FIGS. 17A and 17B are diagrams illustrating a part of a procedure of a manufacturing method of a semiconductor memory device according to a first modification of the first embodiment;

FIG. 18 is a diagram illustrating a part of a procedure of a manufacturing method of a semiconductor memory device according to a second modification of the first embodiment;

FIGS. 19A to 19C are schematic diagrams illustrating layouts in the process of manufacturing a semiconductor memory device according to a third modification of the first embodiment;

FIGS. 20A and 20B are diagrams illustrating a part of a procedure of a manufacturing method of a semiconductor memory device according to a comparative example;

FIGS. 21A and 21B are diagrams illustrating a part of the procedure of the manufacturing method of the semiconductor memory device according to the comparative example;

FIG. 22 is a block diagram illustrating an example of a physical configuration of a design device according to a second embodiment;

FIG. 23 is a block diagram illustrating an example of a functional configuration of the design device according to the second embodiment;

FIGS. 24A and 24B are schematic diagrams illustrating an example of a design operation of the arrangement of contact holes by the design device according to the second embodiment;

FIGS. 25A and 25B are schematic diagrams illustrating a variation example of the arrangement of the contact holes by the design device according to the second embodiment;

FIG. 26 is a flowchart illustrating an example of a procedure of design processing of the contact hole arrangement by the design device according to the second embodiment;

FIGS. 27A and 27B are schematic diagrams illustrating an example of a design operation of arrangement of contact holes by a design device according to a modification of the second embodiment; and

FIG. 28 is a flowchart illustrating an example of a procedure of designing processing of the contact hole arrangement by the design device according to the modification of the second embodiment.

### DETAILED DESCRIPTION

In general, a design method according to one embodiment is a design method of determining an arrangement of a plurality of holes having different reaching depths, the design method including: calculating, in a case in which one or more restrictions related to design are present and in a case in which a resin layer covering the plurality of holes having a first arrangement satisfying the one or more restrictions is formed, a first layer thickness difference in the resin layer on the plurality of holes, the first layer thickness difference being generated by allowing a part of the resin layer to flow into the plurality of holes; determining whether the first layer thickness difference is equal to or less than a predetermined upper limit value; calculating, when the first layer thickness difference exceeds the upper limit value, a second layer thickness difference generated in the resin layer on the plurality of holes in a case in which the arrangement of the plurality of holes is changed to a second arrangement satisfying the one or more restrictions; determining whether the second layer thickness difference is equal to or less than the upper limit value; and adopting the second arrangement when the second layer thickness difference is equal to or less than the upper limit value.

Hereinafter, embodiments of the present invention will be described in detail with reference to the drawings. It is noted that the present invention is not limited by the following embodiments. In addition, constituent elements in the following embodiments include those that can be easily assumed by those skilled in the art or those that are substantially the same.

### First Embodiment

Hereinafter, a first embodiment will be described in detail with reference to the drawings.

### Configuration Example of Semiconductor Memory Device

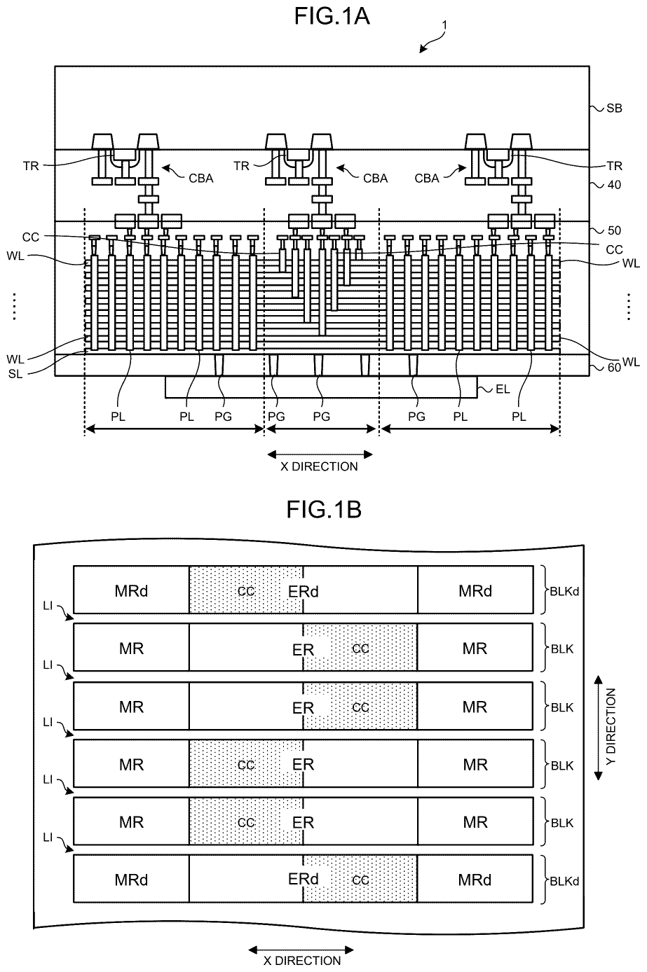

FIGS. 1A and 1B are schematic diagrams each illustrating a schematic configuration example of a semiconductor memory device 1 according to a first embodiment. More specifically, FIG. 1A is a cross-sectional view of the semiconductor memory device 1 in the X direction, and FIG. 1B is a schematic plan view illustrating a layout of the semiconductor memory device 1.

However, in FIG. 1A, hatching is omitted in consideration of visibility of the drawing. In FIG. 1A, some upper layer wirings and the like are omitted.

In the present specification, both the X direction and the Y direction are directions oriented toward the surface of a word line WL, and the X direction and the Y direction are orthogonal to each other. In addition, the electrical drawing direction of the word line WL may be referred to as a first direction, and the first direction is a direction in the X direction. In addition, a direction intersecting the first direction may be referred to as a second direction, and the second direction is a direction in the Y direction. However, since the semiconductor memory device 1 may include a manufacturing error, the first direction and the second direction are not necessarily orthogonal to each other.

As illustrated in FIG. 1A, the semiconductor memory device 1 includes an electrode film EL, a source line SL, and a plurality of word lines WL in order from the lower side of the drawing. In addition, the semiconductor memory device 1 includes a peripheral circuit CBA provided on a semiconductor substrate SB above the plurality of word lines WL.

The source line SL is disposed on the electrode film EL with an insulating layer 60 interposed therebetween. A plurality of plugs PG are disposed in the insulating layer 60, and the source line SL and the electrode film EL maintain electrical conduction with the plugs PG interposed therebetween. As a result, the source potential can be applied to the source line SL from the outside of the semiconductor memory device 1 via the electrode film EL and the plug PG. A plurality of word lines WL are stacked on the source line SL.

As illustrated in FIGS. 1A and 1B, a contact region ER is disposed at the center of the plurality of word lines WL, and memory regions MR are respectively disposed at both end portions of the plurality of word lines WL. The contact region ER and the memory region MR are divided into a plurality of regions by a plurality of plate-shaped contacts LI penetrating the plurality of word lines WL and the like and extending in the direction along the X direction.

It is noted that a region that is disposed between the plate-shaped contacts LI adjacent to each other in the Y direction and includes the contact region ER and the memory region MR is referred to as a block region BLK. As will be described later, the memory region MR includes a plurality of memory cells that store data in a nonvolatile manner, and the block region BLK is an erase unit of the data.

Further, among the plurality of block regions BLK arranged in the Y direction, the block regions BLK respectively disposed at both end portions in the Y direction are dummy blocks BLKd each having a dummy contact region ERd and a dummy memory region MRd. The contact region ERd and the memory region MRd do not contribute to the operation of the semiconductor memory device 1, but may be configured similarly to the normal contact region ER and the memory region MR to be described later. As described above, by providing the dummy block region BLK, even if the quality deteriorates at the end portion in the Y direction, it is possible to suppress the influence on the quality of the entire semiconductor memory device 1.

In the memory region MR, a plurality of pillars PL penetrating the word line WL in the stacking direction are arranged. A plurality of memory cells are formed at intersections between the pillars PL and the word lines WL. As a result, the semiconductor memory device 1 is configured as, for example, a three-dimensional nonvolatile memory in which memory cells are three-dimensionally arranged in the memory region MR.

In the contact region ER, a plurality of contacts CC connected to each of the plurality of word lines WL are arranged. In the present specification, in the extending direction of the contact CC, the connection end side of the contact CC with the word line WL is defined as the lower side of the semiconductor memory device 1.

From the contact CC, a write voltage, a read voltage, and the like are applied to a memory cell included in the memory region MR at the central portion of the plurality of word lines WL via the word line WL at the same height position as that of the memory cell. In this manner, the word lines WL stacked in multiple layers are individually drawn out by these contacts CC.

As illustrated in FIG. 1B, in the contact region ER arranged in the central portion of the plurality of word lines WL, the arrangement positions of the plurality of contacts CC are shifted in the X direction for each of the two block regions BLK. That is, in FIG. 1B, when two block regions BLK adjacent to each other in the Y direction have the arrangement region of the contact CC near the memory region MR on the right side of the drawing, the next two block regions BLK adjacent to each other in the Y direction to these block regions BLK have the arrangement region of the contact CC near the memory region MR on the left side of the drawing.

With such an alternate arrangement, the wiring path connected to each of the plurality of contacts CC can be secured, and the voltage applied to the memory cell can be supplied to the plurality of contacts CC.

As illustrated in FIG. 1A, the plurality of word lines WL, pillars PL, and contacts CC are covered with an insulating layer 50. The insulating layer 50 also extends around the periphery of the plurality of word lines WL.

The semiconductor substrate SB above the insulating layer 50 is, for example, a silicon substrate or the like. The peripheral circuit CBA including a transistor TR, wiring, and the like is disposed on the surface of the semiconductor substrate SB. Various voltages applied from the contacts CC to the memory cells are controlled by peripheral circuits CBA electrically connected to the contacts CC. In this manner, the peripheral circuit CBA controls the electrical operation of the memory cell.

The peripheral circuit CBA is covered with an insulating layer 40, and the insulating layer 40 and the insulating layer 50 covering a stacked body LM are bonded to each other, thereby forming the semiconductor memory device 1 including the configuration of the plurality of word lines WL, pillars PL, contacts CC, and the like, and the peripheral circuit CBA.

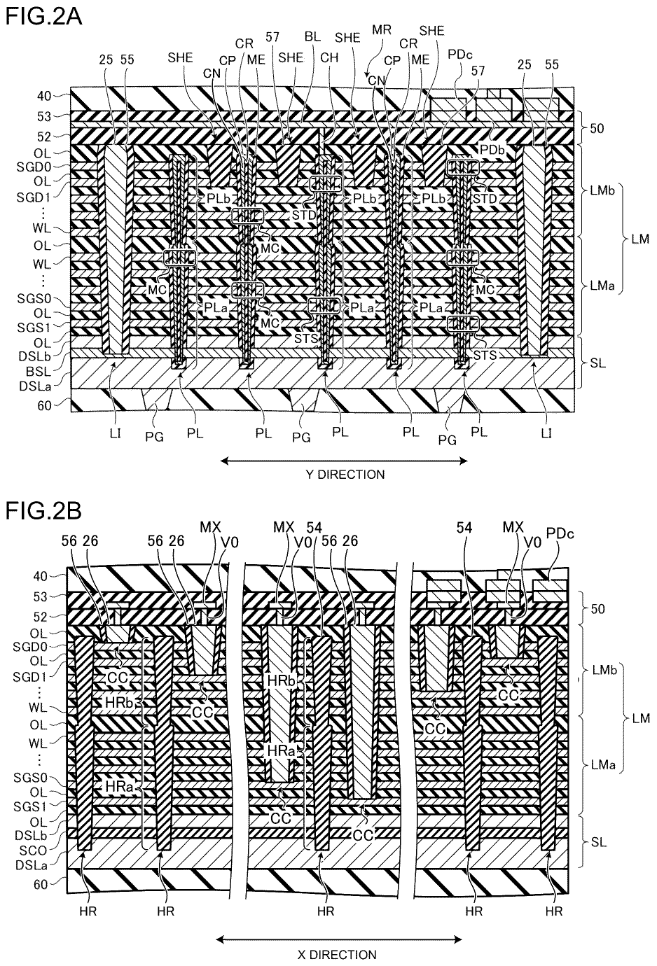

Next, a detailed configuration example of the semiconductor memory device 1 will be described with reference to FIGS. 2A and 2B. FIGS. 2A and 2B are cross-sectional views illustrating an example of a configuration of the semiconductor memory device 1 according to the first embodiment.

More specifically, FIG. 2A is a cross-sectional view in the Y direction, illustrating an example of the configuration of the memory region MR. FIG. 2B is a cross-sectional view in the X direction, illustrating an example of the configuration of the contact region ER. However, in FIGS. 2A and 2B, structures below the insulating layer 60 and above the insulating layer 40 are omitted.

As illustrated in FIG. 2A, in the memory region MR, the source line SL has a multilayer structure in which, for example, a lower source line DSLa, an intermediate source line BSL, and an upper source line DSLb are stacked in this order on the insulating layer 60.

The lower source line DSLa, the intermediate source line BSL, and the upper source line DSLb are, for example, polysilicon layers. Among them, at least intermediate source line BSL may be a conductive polysilicon layer or the like in which impurities are diffused.

As illustrated in FIG. 2B, in the contact region ER, the source line SL includes an intermediate insulating layer SCO between the lower source line DSLa and the upper source line DSLb instead of the intermediate source line BSL. This is because the pillar PL to be connected with the source line SL is not disposed in the contact region ER. The intermediate insulating layer SCO is, for example, a silicon oxide layer or the like. However, the source line SL may include the intermediate source line BSL in contact region ER as well.

The stacked body LM is arranged on the source line SL. The stacked body LM includes stacked bodies LMa and LMb in which a plurality of word lines WL and a plurality of insulating layers OL are alternately stacked on each other. The stacked body LMa is disposed above the source line SL, and the stacked body LMb is disposed on the stacked body LMa.

One or more select gate lines SGS are disposed with the insulating layer OL interposed therebetween below the word line WL of the lowermost layer of the stacked body LMa. In the example of FIGS. 2A and 2B, the stacked body LMa includes two select gate lines SGS0 and SGS1 in order from the upper layer side. One or more select gate lines SGD are disposed above the word line WL of the uppermost layer of the stacked body LMb via the insulating layer OL. In the example of FIGS. 2A and 2B, the stacked body LMb includes two select gate lines SGD0 and SGD1 in order from the upper layer side.

However, the number of word lines WL and the select gate lines SGD and SGS stacked in the stacked body LM is arbitrary.

The word line WL and the select gate lines SGD and SGS as the plurality of conductive layers are, for example, a tungsten layer or a molybdenum layer. The plurality of insulating layers OL are, for example, silicon oxide layers.

The insulating layer OL of the uppermost layer of each of the stacked bodies LMa and LMb is thicker than, for example, the other insulating layers OL in the stacked bodies LMa and LMb. The insulating layer OL of the uppermost layer of the stacked body LMa is in contact with the word line WL of the lowermost layer of the stacked body LMb, and insulating layers 52 and 53 are arranged in this order on the insulating layer OL of the uppermost layer of the stacked body LMb. The insulating layers 52 and 53 constitute a part of the insulating layer 50 described above, and the upper surface of the insulating layer 53 is in contact with, for example, the lower surface of the insulating layer 40 on the peripheral circuit CBA side.

As illustrated in FIG. 2A, the stacked body LM is divided in the Y direction by a plurality of plate-shaped contacts LI.

That is, the plate-shaped contacts LI are arranged in the Y direction and extend in the stacking direction of the stacked body LM and the X direction. As described above, the plate-shaped contact LI continuously extends in the stacked body LM including the memory region MR and the contact region ER from one end portion to the other end portion of the stacked body LM in the X direction.

In the memory region MR, the plate-shaped contact LI penetrates the stacked body LM and the upper source line DSLb and reaches the intermediate source line BSL. In the contact region ER, the plate-shaped contact LI penetrates the stacked body LM and the upper source line DSLb and reaches the intermediate insulating layer SCO.

Each of the plate-shaped contacts LI includes an insulating layer 55 and a conductive layer 25. The insulating layer 55 is, for example, a silicon oxide layer or the like. The conductive layer 25 is, for example, a tungsten layer or a conductive polysilicon layer.

The insulating layer 55 covers the side walls of the plate-shaped contact LI facing each other in the Y direction. The inside of the insulating layer 55 is filled with the conductive layer 25. However, instead of the plate-shaped contact LI, the plate member filled with the insulating layer may penetrate the stacked body LM and may extend in the direction along the X direction, thereby dividing the stacked body LM in the Y direction.

A plurality of separation layers SHE are disposed between the plate-shaped contacts LI adjacent to each other in the Y direction. These separation layers SHE are insulating layers 57 such as a silicon oxide layer that penetrates the select gate lines SGD0 and SGD1 of the stacked body LMb, reaches the insulating layer OL directly below the select gate line SGD1, and extends in the direction along the X direction in the memory region MR of the stacked body LM. With such a configuration, the separation layer SHE selectively separates the select gate lines SGD0 and SGD1 between the plate-shaped contact LI in the Y direction.

In the memory region MR of the stacked body LM, a plurality of pillars PL penetrating the stacked body LM, the upper source line DSLb, and the intermediate source line BSL and reaching the lower source line DSLa are dispersedly arranged.

The plurality of pillars PL take, for example, a staggered periodic arrangement when viewed from the stacking direction of the stacked body LM. Each pillar PL has, for example, a circular shape, an elliptical shape, an oval shape (oval shape), or the like as a cross-sectional shape in a direction along the layer direction of the stacked body LM, that is, in a direction along the XY plane.

The pillar PL includes a pillar PLa that penetrates the stacked body LMa from the insulating layer OL of the uppermost layer of the stacked body LMa and reaches the source line SL, and a pillar PLb that penetrates the stacked body LMb from the insulating layer OL of the uppermost layer of the stacked body LMb, reaches the insulating layer OL of the uppermost layer of the stacked body LMa, and is connected to the upper end portion of the corresponding pillar PLa.

Each of the plurality of pillars PL includes a memory layer ME extending in the stacked body LM in the stacking direction, a channel layer CN formed to penetrate the stacked body LM and connected to the intermediate source line BSL, and a core layer CR serving as a core material of the pillar PL.

The memory layer ME is disposed on the side surface of the pillar PL except for the depth position of the intermediate source line BSL. In addition, the memory layer ME is also disposed on the bottom surface of the pillar PL reaching the depth of the lower source line DSLa. It is noted that the memory layer ME has a multilayer structure in which a block insulating layer, a charge storage layer, and a tunnel insulating layer (all not illustrated) are stacked in this order from the outer peripheral side of the pillar PL.

The channel layer CN penetrates the stacked body LM, the upper source line DSLb, and the intermediate source line BSL inside the memory layer ME and reaches the depth of the lower source line DSLa. That is, the channel layer CN is disposed on the side surface and the bottom surface of the pillar PL via the memory layer ME. The core layer CR is filled further inside the channel layer CN.

However, a part of the channel layer CN is in contact with the intermediate source line BSL on the side surface, and is electrically connected to the source line SL including the intermediate source line BSL. In addition, the cap layer CP is disposed at the upper end portion of the channel layer CN, and is connected to a bit line BL extending in the direction along the Y direction in the insulating layer 53 via a plug CH disposed in the insulating layer 52.

In the cross section in FIG. 2A, only one pillar PL among the five pillars PL between the plate-shaped contacts LI adjacent to each other in the Y direction is connected to the bit line BL via the plug CH. The other pillars PL disposed between the plate-shaped contacts LI are respectively connected to the bit lines BL different from the bit line BL in FIG. 2A via the plug CH different from the plug CH in FIG. 2A at positions different from the cross section in FIG. 2A.

The block insulating layer and the tunnel insulating layer of the memory layer ME, and the core layer CR are, for example, silicon oxide layers. The charge storage layer of the memory layer ME is, for example, a silicon nitride layer or the like. The channel layer CN is, for example, a semiconductor layer such as a polysilicon layer or an amorphous silicon layer.

With the above configuration, memory cells MC are respectively formed in portions facing the individual word lines WL on the side surfaces of the pillars PL. When a predetermined voltage is applied from the word line WL, data is written to and read from the memory cell MC.

Data from the memory cell MC is read out to the bit line BL connected to the pillar PL. The bit line BL is connected to an electrode pad PDb disposed on the surface of the insulating layer 53. The electrode pad PDb is disposed on the surface of the insulating layer 40 and is connected to an electrode pad PDc electrically connected to the peripheral circuit CBA. As a result, the data of the memory cell MC read out to the bit line BL is processed by the peripheral circuit CBA.

In addition, with the above configuration, select gates STD are respectively formed at portions of the side surfaces of the pillars PL, which face respective select gate lines SGD. In addition, select gates STS are respectively formed at portions of the side surfaces of the pillars PL, which face the respective select gate lines SGS. When a predetermined voltage is applied from the select gate lines SGD and SGS, the select gates STD and STS are turned on or off, and the memory cells MC formed in the pillars PL to which these select gates STD and STS belong are brought into a selected state or a non-selected state.

As illustrated in FIG. 2B, a plurality of contacts CC and a plurality of columnar portions HR are arranged in the contact region ER.

Some of the contacts CC extend in the stacked body LMb in the stacking direction of the stacked body LM and are connected to any one of one or more select gate lines SGD or a plurality of word lines WL included in the stacked body LMb, respectively.

Some of the contacts CC extend in the stacked bodies LMa and LMb in the stacking direction of the stacked body LM, and are connected to any one of the one or more select gate lines SGS belonging to the stacked body LMa. Although not illustrated in the drawing, some other contacts CC extending in the stacked bodies LMa and LMb are also connected to the plurality of word lines WL included in the stacked body LMa.

More specifically, in the semiconductor memory device 1 of the first embodiment, in the array in which the plurality of contacts CC are arranged in the X direction, about half of the contacts CC are connected to the odd-numbered word lines WL and the select gate lines SGD and SGS counted from the upper layer side of the stacked body LM. On the other hand, the remaining contacts CC are connected to the even-numbered word lines WL and the select gate lines SGD and SGS counted from the upper layer side of the stacked body LM.

In addition, the contact CC connected to the odd-numbered word line WL or the like and the contact CC connected to the even-numbered word line WL or the like increase in reaching depth from the side far from the contact CC to the side close thereto. That is, the contacts CC are arranged side by side in the X direction so as to be connected to the lower word line WL and the like.

In FIG. 2B, the contact CC connected to the select gate line SGD0 of the uppermost layer, the word line WL of the uppermost layer, and the select gate line SGS0 of the upper layer side is illustrated as an example of the contact CC connected to the odd-numbered word line WL and the like from the left side of the drawing. In addition, following the contact CC connected to the select gate line SGS0, the contact CC connected to the select gate line SGS1 of the lowermost layer, the second word line WL from the uppermost layer, and the second select gate line SGD0 from the uppermost layer is illustrated as an example of the contact CC connected to the even-numbered word line WL and the like to the right side of the drawing.

It is noted that, in the actual semiconductor memory device 1, the number of stacked layers of the word lines WL and the like ranges from several tens of layers to several hundreds of layers. Therefore, the contacts CC arranged in the X direction as described above may be arranged in a plurality of rows while being separated from each other in the Y direction. Even in this case, all of the contacts CC in the plurality of columns are connected to the word lines WL and the like in different layers.

Each of these contacts CC has an insulating layer 56 covering the outer periphery of the contact CC, and a conductive layer 26 such as a tungsten layer or a copper layer filling the inside of the insulating layer 56.

The conductive layer 26 of the contact CC is connected to an upper layer wiring MX disposed in the insulating layer 53 via a plug V0 disposed in the insulating layer 52. The upper layer wiring MX is electrically connected to the above-described peripheral circuit CBA (refer to FIG. 1A) via the electrode pad PDb on the surface of the insulating layer 53, the electrode pad PDc on the surface of the insulating layer 40, and the like.

It is noted that, in the region sandwiched by the plate-shaped contacts LI, the plurality of separation layers SHE extend in the direction along the X direction in the memory region MR between the plate-shaped contacts LI, and also extend in the direction along the X direction in a portion where the plurality of contacts CC connected to the select gate line SGD are arranged in the contact region ER.

As a result, the select gate line SGD is sandwiched between the plate-shaped contact LI and the separation layer SHE or the two separation layers SHE on both sides in the Y direction, and the end portion in the X direction is selectively separated into a plurality of regions separated by the separation layer SHE. Each of the contacts CC is connected to a corresponding one of the plurality of regions of the select gate line SGD separated by the plate-shaped contact LI and the separation layer SHE.

With such a configuration, the word lines WL and the select gate lines SGD and SGS of the respective layers can be electrically drawn.

That is, with the above configuration, a predetermined voltage can be applied from the peripheral circuit CBA to the memory cell MC via the upper layer wiring MX, the contact CC, and the word line WL to operate the memory cell MC as a storage element.

In addition, a predetermined voltage is applied from the peripheral circuit CBA to the select gates STD and STS via the upper layer wiring MX, the contact CC, and the select gate lines SGD and SGS, and the memory cell MC can be brought into a selected state or a non-selected state. At this time, the memory cell MC is in a selected state or a non-selected state for each region separated by the plate-shaped contact LI and the separation layer SHE.

In the contact region ER in which the plurality of contacts CC are arranged, a plurality of columnar portions HR penetrating the stacked body LM, the upper source line DSLb, and the intermediate insulating layer SCO and reaching the lower source line DSLa are arranged in a distributed manner.

The plurality of columnar portions HR are arranged substantially periodically in a grid shape or a zigzag shape, for example, when viewed from the stacking direction of the stacked body LM. The reason why the arrangement of the plurality of columnar portions HR is substantially periodic is that, since the columnar portions HR are arranged while avoiding interference with the plurality of contacts CC and the plate-shaped contact LI, the periodicity of the arrangement of the columnar portions HR slightly collapses around the plurality of contacts CC and the plate-shaped contact LI.

Each of the columnar portions HR has, for example, a circular shape, an elliptical shape, an oval shape, or the like as a cross-sectional shape in a direction along the XY plane.

Each columnar portion HR includes a columnar portion HRa that penetrates the stacked body LMa from an insulating layer OLc of the uppermost layer of the stacked body LMa and reaches the source line SL, and a columnar portion HRb that penetrates the stacked body LMb from the insulating layer OLc of the uppermost layer of the stacked body LMb, reaches the insulating layer OLc of the uppermost layer of the stacked body LMa, and is connected to the upper end portion of the corresponding columnar portion HRa.

As will be described later, these columnar portions HR have a role of supporting these configurations when forming the stacked body LM from the stacked body in which the sacrificial layer and the insulating layer are stacked on each other, and are dummy pillars that do not contribute to the function of the semiconductor memory device 1. Therefore, each of the columnar portions HRa and HRb is configured by a single body of the insulating layer 54 such as a silicon oxide layer, and is configured such that the columnar portion HR does not electrically affect other configurations.

Further, at the identical height position of the stacked body LM, the cross-sectional area of the columnar portion HR in the direction along the XY plane may be larger than, for example, the cross-sectional area of the pillar PL in the direction along the XY plane. In addition, a pitch between the plurality of columnar portions HR may be larger than, for example, a pitch between the plurality of pillars PL. In the XY plane, arrangement density of the columnar portions HR per unit area of the word line WL in the stacked body LM may be lower than arrangement density of the pillars PL per unit area of the word line WL.

As described above, for example, by configuring the cross-sectional area of the pillars PL to be smaller and having a narrower pitch than that of the columnar portion HR, a large number of memory cells MC can be formed at a high density in the stacked body LM having a predetermined size, and the storage capacity of the semiconductor memory device 1 can be increased. On the other hand, since the columnar portion HR is exclusively used to support the stacked body LM, it is possible to reduce the manufacturing load of the semiconductor memory device 1 by not having, for example, a precise configuration with a small cross-sectional area and a narrow pitch like the pillars PL.

### Manufacturing Method of Semiconductor Memory Device

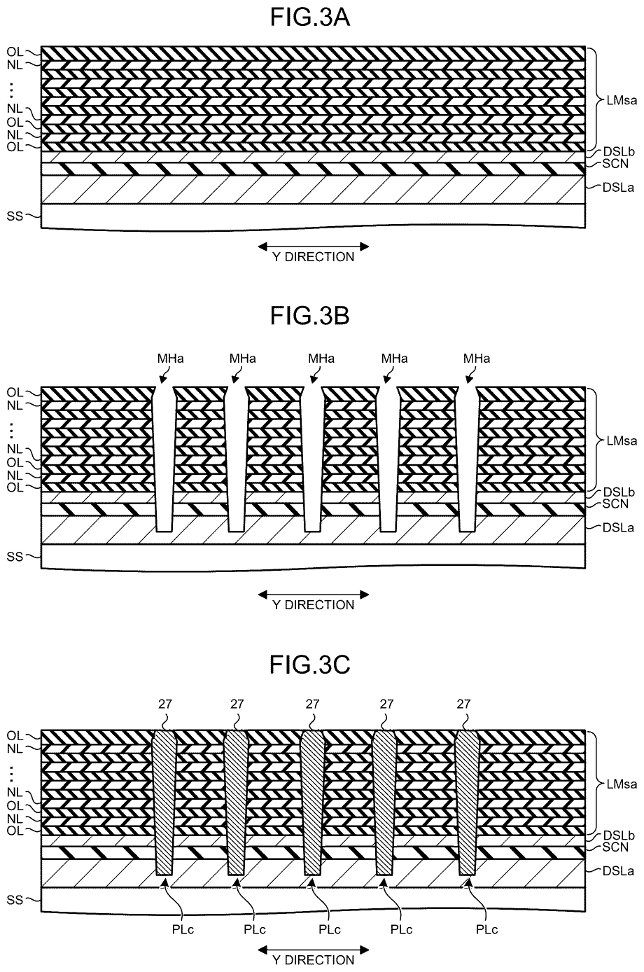

Next, a manufacturing method of the semiconductor memory device 1 according to the first embodiment will be described with reference to FIGS. 3A to 16B. FIGS. 3A to 16B are diagrams sequentially illustrating a part of a procedure of the manufacturing method of the semiconductor memory device 1 according to the first embodiment.

First, FIGS. 3A to 6B illustrate how the pillars PL are formed in a configuration to be the stacked body LM later. FIGS. 3A to 6B illustrate a cross section in the Y direction of the semiconductor memory device 1 in the middle of manufacturing, including a region to be the memory region MR later.

As illustrated in FIG. 3A, lower source line DSLa, intermediate sacrificial layer SCN, and upper source line DSLb are formed in this order on support substrate SS.

As the support substrate SS, a semiconductor substrate such as a silicon substrate, an insulating substrate such as a ceramic substrate, a conductive substrate, or the like can be used. The insulating layer 60 (refer to FIG. 2A and the like) described above may be formed on the upper surface side of the support substrate SS.

The intermediate sacrificial layer SCN is, for example, a silicon nitride layer or the like, and is a layer to be replaced with a polysilicon layer or the like later and become the intermediate source line BSL. It is noted that, although not illustrated in the drawing, in a region to be the contact region ER later, the intermediate insulating layer SCO is formed between the lower source line DSLa and the upper source line DSLb.

A stacked body LMsa in which a plurality of insulating layers NL and a plurality of insulating layers OL are alternately stacked on each other is formed on the upper source line DSLb. The insulating layer NL is, for example, a silicon nitride layer or the like, and functions as a sacrificial layer that is later replaced with a conductive material and becomes the word line WL or the select gate line SGS.

As illustrated in FIG. 3B, a plurality of memory holes MHa extending in the stacking direction of the stacked body LMsa are formed. The plurality of memory holes MHa penetrate the stacked body LMsa, the upper source line DSLb, and the intermediate sacrificial layer SCN, and reach the lower source line DSLa. These memory holes MHa are portions to be the pillars PLa later.

As illustrated in FIG. 3C, the memory holes MHa are filled with a sacrificial layer 27 such as an amorphous silicon layer or a CVD-carbon layer. As a result, pillars PLc in which the plurality of memory holes MHa are filled with the sacrificial layers 27 are formed.

It is noted that, in the region to be the contact region ER later, a configuration in which a through hole of the stacked body LMsa is filled with the sacrificial layer to be the columnar portion HRa later is formed in parallel with the processing of FIGS. 3B and 3C.

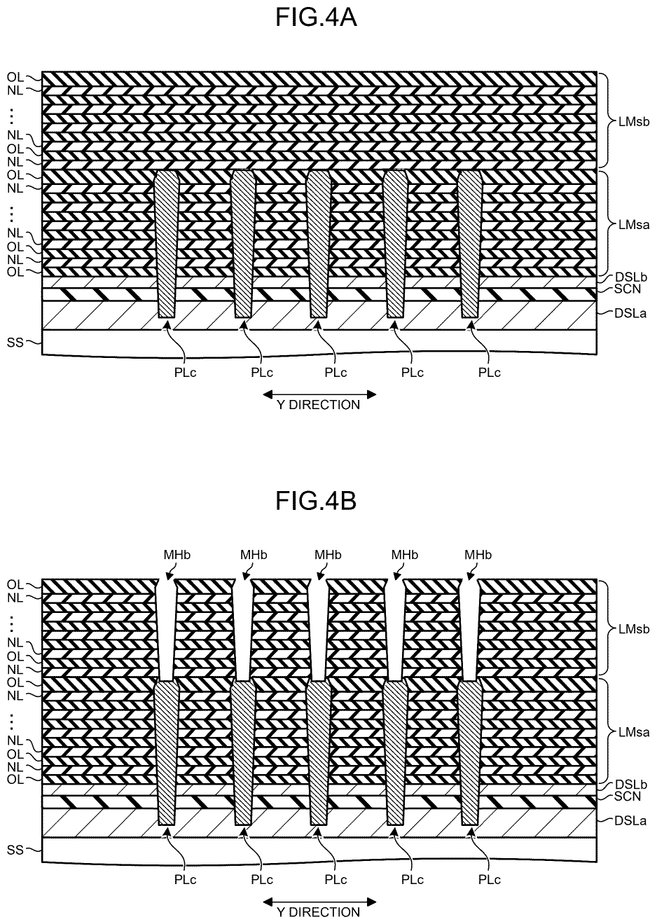

As illustrated in FIG. 4A, the stacked body LMsa is covered, and a stacked body LMsb in which a plurality of insulating layers NL and a plurality of insulating layers OL are alternately stacked on each other is formed. The insulating layer NL of the stacked body LMsb functions as a sacrificial layer that is later replaced with a conductive layer and becomes the word line WL or the select gate line SGD.

As illustrated in FIG. 4B, a plurality of memory holes MHb formed to penetrate the stacked body LMsb and respectively connected to the plurality of pillars PLc formed in the stacked body LMsa are formed. The memory hole MHb is a portion that becomes the pillar PLb later.

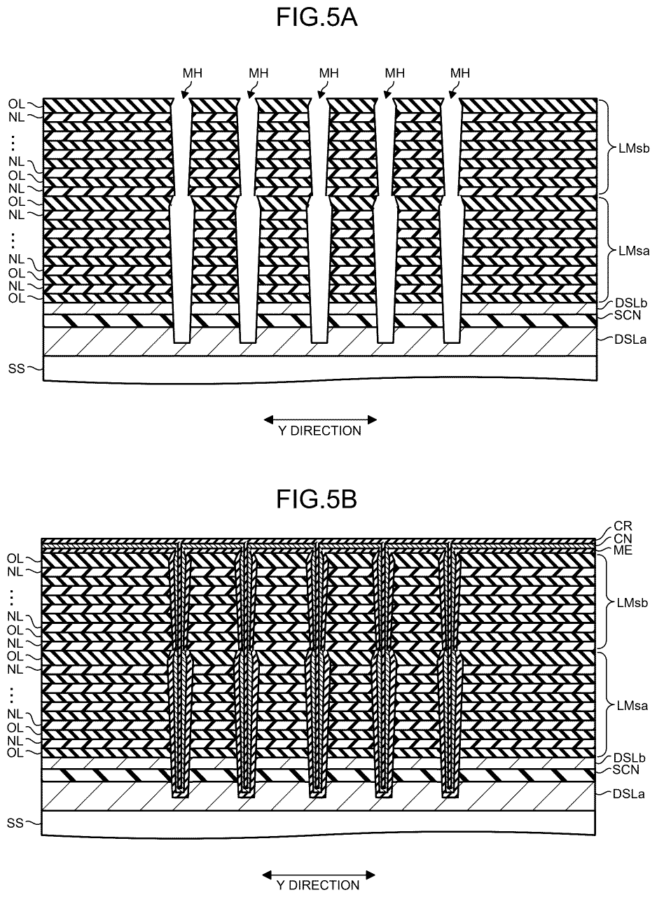

As illustrated in FIG. 5A, the sacrificial layer 27 is removed from the pillar PLc at the bottom of the memory hole MHb. As a result, the memory holes MHa are opened at the bottoms of the plurality of memory holes MHb, and a plurality of memory holes MH penetrating the stacked bodies LMsb and LMsa, the upper source line DSLb, and the intermediate sacrificial layer SCN and reaching the lower source line DSLa are formed.

It is noted that, in a case where the sacrificial layer 27 filling the inside of the pillar PLc is a CVD-carbon layer or the like, each of the sacrificial layers 27 can be collectively removed from a corresponding one of the pillars PLc when a mask pattern or the like used at the time of forming the memory hole MHb in FIG. 4B described above is removed by ashing or the like using oxygen plasma.

In addition, in the region to be the contact region ER later, a through hole is formed in the stacked body LMsb in parallel with the processing in FIGS. 4B and 5A, and the through hole is connected to the configuration to be the columnar portion HRa later, and then the sacrificial layer is removed. Furthermore, for example, prior to the following processing in FIG. 5B, the insulating layer 54 (refer to FIG. 2B) fills, for example, the through hole penetrating the stacked bodies LMsb and LMsa, and the above-described columnar portion HR is formed.

As illustrated in FIG. 5B, a memory layer ME including a block insulating layer, a charge storage layer, and a tunnel insulating layer (all not illustrated) in this order from the side wall side of the memory hole MH is formed on the side wall of the memory hole MH and the bottom surface from which the lower source line DSLa is exposed. The memory layer ME is also formed on the upper surface of the stacked body LMsb.

In addition, the channel layer CN and the core layer CR are formed in this order in the memory hole MH via the memory layer ME. As a result, the memory layer ME and the channel layer CN covering the side surface and the bottom surface of the memory hole MH are formed in this order, and the central portion of the memory hole MH is filled with the core layer CR. The channel layer CN and the core layer CR are also formed in this order on the upper surface of the stacked body LMsb with the memory layer ME interposed therebetween.

Thereafter, the core layer CR, the channel layer CN, and the memory layer ME on the upper surface of the stacked body LMsb are removed in this order. At this time, the core layer CR in the memory hole MH is retracted to form a recess in the upper end portion of the memory hole MH.

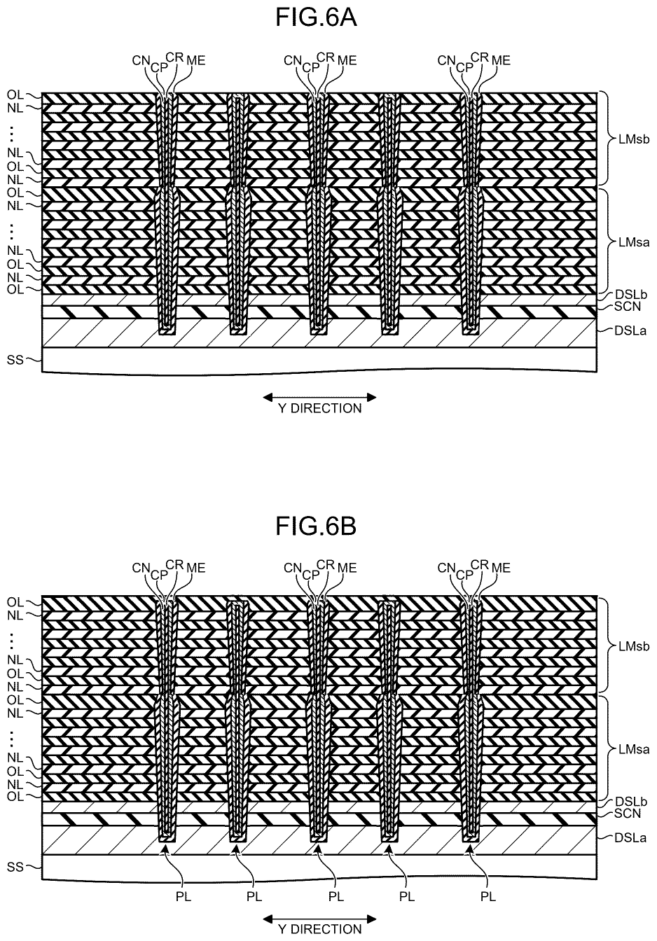

As illustrated in FIG. 6A, a cap layer CP is formed in the recess at the upper end portion of the memory hole MH. The cap layer CP is also formed on the upper surface of the stacked body LMsb. The cap layer CP on the upper surface of the stacked body LMsb is removed together with a part of the insulating layer OL of the uppermost layer of the stacked body LMsb.

As illustrated in FIG. 6B, the insulating layer OL of the uppermost layer of the stacked body LMsb thinned by CMP or the like is stacked. As a result, the pillar PL in which the cap layer CP is buried in the insulating layer OL of the uppermost layer is formed. However, at this point, the memory layer ME covers the entire sidewall of the pillar PL, and a part of the side surface of the channel layer CN is not exposed from the memory layer ME.

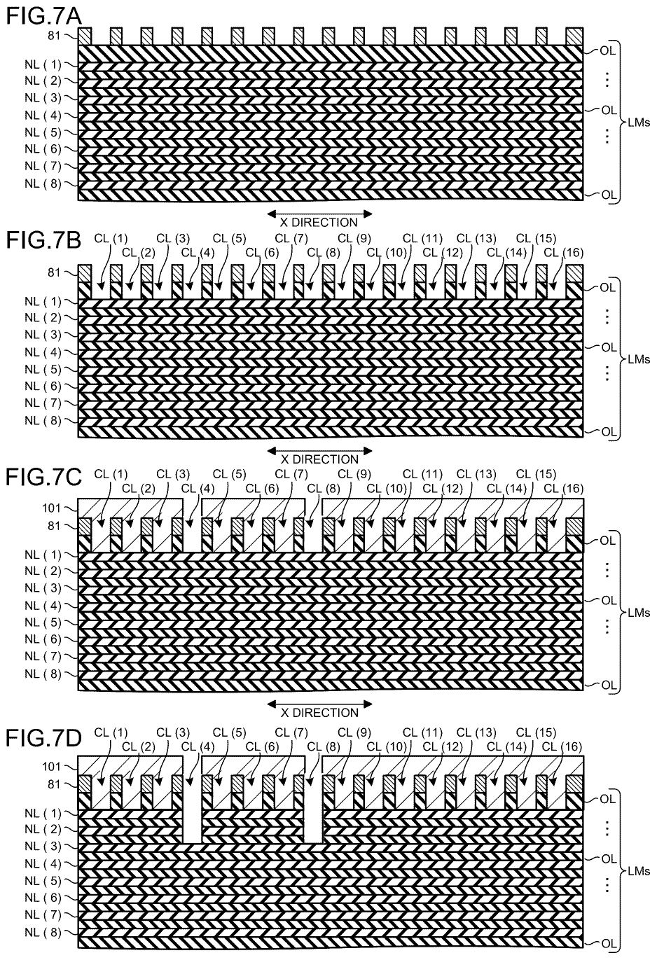

Next, a state in which the contact hole CL to be the contact CC later is formed in the stacked bodies LMsa and LMsb is illustrated in FIGS. 7A to 11B. FIGS. 7A to 11B illustrate a cross section in the X direction of the semiconductor memory device 1 in the middle of manufacturing, including a region to be the contact region ER later.

However, in FIGS. 7A to 11B, as an example, an example is illustrated in which contact holes CL(1) to CL(16) respectively reaching the depth positions of the 16 insulating layers NL of the stacked body LMs are formed. In addition, the plurality of columnar portions HR are not illustrated in FIGS. 7A to 11B, and the lower layer portion of the stacked body LMs is not illustrated in FIGS. 7A to 10C.

As described below, the plurality of contact holes CL having different reaching depths are formed by forming a resist pattern a plurality of times, exposing the different contact holes CL each time, and processing the contact holes CL to different depths.

As illustrated in FIG. 7A, a hard mask pattern 81 having a plurality of openings is formed on the upper surface of the stacked body LMs. The hard mask pattern 81 is an inorganic layer that is not removed by ashing using, for example, oxygen plasma. Each of the plurality of openings of the hard mask pattern 81 has, for example, a hole shape.

As illustrated in FIG. 7B, the upper surface of the stacked body LMs exposed from the opening of the hard mask pattern 81 is etched to remove the insulating layer OL of the uppermost layer. As a result, a plurality of contact holes CL each penetrating the insulating layer OL of the uppermost layer and reaching the insulating layer NL directly below the insulating layer OL are formed.

It is noted that, as illustrated in the drawing, hereinafter, the uppermost layer, the second, third . . . , from the uppermost layer, and the insulating layers NL of the lowermost layer are respectively referred to as insulating layers NL(1), NL(2), NL(3) . . . , NL(16). The first, second, third . . . , and 16th contact holes CL from the left side of the drawing are respectively referred to as contact holes CL(1), CL(2), CL(3) . . . , CL(16).

That is, in FIG. 7B, the contact holes CL(1) to(16) reaching the insulating layer NL(1) are formed.

Subsequently, processing is divided into, for example, processing for the contact hole CL that reaches the odd-numbered insulating layer NL and processing for the contact hole CL that reaches the even-numbered insulating layer NL among the plurality of contact holes CL.

First, a processing procedure of the contact hole CL on the left half of the drawing, which reaches the odd-numbered insulating layer NL among the plurality of contact holes CL, will be described below.

As illustrated in FIG. 7C, a resist pattern 101 having a plurality of openings is formed by partially covering the upper surface of the stacked body LMs with the hard mask pattern 81 interposed therebetween. The resist pattern 101 is, for example, an organic layer such as a photoresist layer that can be removed by ashing or the like using oxygen plasma, and is formed by a spin coating method or the like. For example, the contact holes CL(4) and CL(8) are exposed from the opening of the resist pattern 101.

As illustrated in FIG. 7D, the contact holes CL(4) and CL(8) exposed from the opening of the resist pattern 101 are further etched, and the contact holes CL(4) and CL(8) penetrate the insulating layers NL for two layers and reach the insulating layers NL below the two layers. As a result, both the contact holes CL(4) and CL(8) reach the insulating layer NL(3).

As described above, by forming the hard mask pattern 81 in advance, even if slight positional deviation occurs at the time of forming the resist pattern 101, it is possible to suppress significant deviation of the additionally processed portions from the initial formation positions of the contact holes CL(4) and CL(8) by such additional processing of the contact holes CL(4) and CL(8).

Thereafter, the resist pattern 101 is removed by ashing using oxygen plasma or the like.

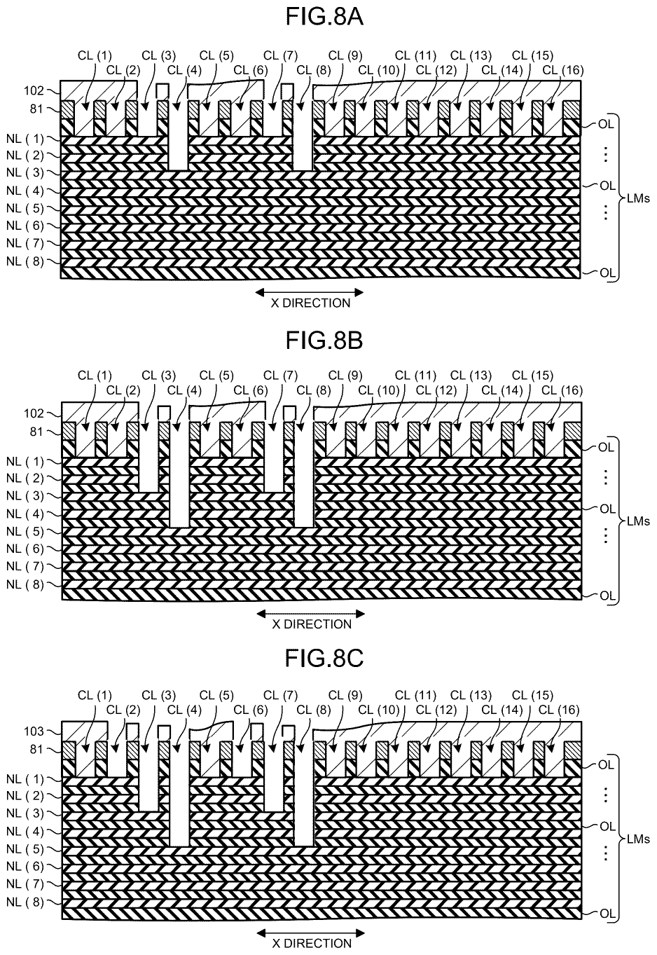

As illustrated in FIG. 8A, a resist pattern 102 partially covering the upper surface of the stacked body LMs with the hard mask pattern 81 interposed therebetween and having a plurality of openings is formed. For example, the contact holes CL(3), CL(4), CL(7), and CL(8) are exposed from the opening of the resist pattern 102.

It is noted that, as the reaching depth of each contact hole CL increases, the amount of a resist material flowing into these contact holes CL increases when a resist layer is formed by a spin coating method or the like, and the thickness of the resist pattern on the upper surface of the stacked body LMs becomes uneven. That is, the resist pattern above the deeper contact hole CL becomes thinner than the other portions.

In addition, as the reaching depth of each contact hole CL increases, in a case where the opening portion of the resist pattern is formed above the contact hole CL of the deep hole, the resist material in the contact hole CL may not be completely removed only by exposure and development. In such a case, the resist material in the contact hole CL is removed by, for example, etching back the entire surface of the resist pattern after exposure and development.

As illustrated in FIG. 8B, the contact holes CL(3), CL(4), CL(7), and CL(8) exposed from the opening of the resist pattern 102 are further etched to penetrate the two insulating layers NL and reach the insulating layers NL below the two insulating layers NL.

As a result, the contact holes CL(4) and CL(8) reach the insulating layer NL(5), and the contact holes CL(3) and CL(7) reach the insulating layer NL(3). In this case as well, the hard mask pattern 81 suppresses positional deviation of the contact holes CL(3), CL(4), CL(7), and CL(8).

Thereafter, the resist pattern 102 is removed by ashing using oxygen plasma or the like.

As illustrated in FIG. 8C, a resist pattern 103 partially covering the upper surface of the stacked body LMs with the hard mask pattern 81 interposed therebetween and having a plurality of openings is formed. For example, the contact holes CL(2), CL(3), CL(4), CL(6), CL(7), and CL(8) are exposed from the opening of the resist pattern 103. In this case as well, the resist material in the contact hole CL of the deep hole is removed by, for example, etching back the entire surface of the resist pattern 103 after exposure and development, as necessary.

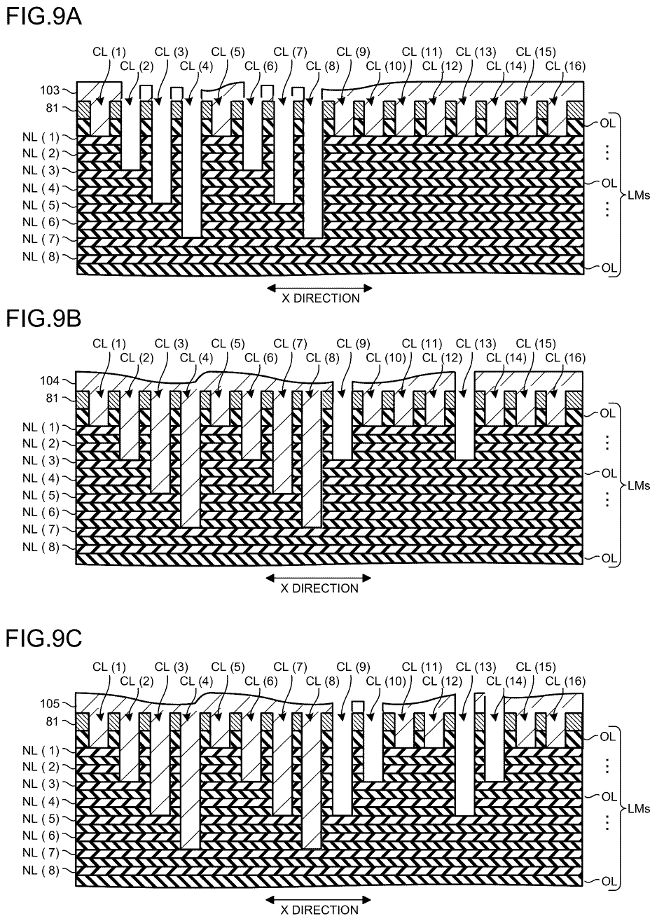

As illustrated in FIG. 9A, the contact holes CL(2), CL(3), CL(4), CL(6), CL(7), and CL(8) exposed from the opening of the resist pattern 103 are further etched to penetrate the insulating layers NL for two layers and reach the insulating layers NL below the two layers.

As a result, the contact holes CL(4) and CL(8) reach the insulating layer NL(7), the contact holes CL(3) and CL(7) reach the insulating layer NL(5), and the contact holes CL(2) and CL(6) reach the insulating layer NL(3).

Thereafter, the resist pattern 103 is removed by ashing using oxygen plasma or the like.

Next, a processing procedure of the contact hole CL on the right half of the drawing, which reaches the even-numbered insulating layer NL among the plurality of contact holes CL, will be described below. The contact hole CL that reaches the even-numbered insulating layer NL is also processed in the same procedure as the contact hole CL that reaches the odd-numbered insulating layer NL described above.

As illustrated in FIG. 9B, a resist pattern 104 which covers a part of the upper surface of the stacked body LMs with the hard mask pattern 81 interposed therebetween and exposes the contact holes CL(9) and CL(13) from the plurality of openings is formed. In addition, both the contact holes CL(9) and CL(13) exposed from the opening of the resist pattern 104 reach the insulating layer NL(3).

As illustrated in FIG. 9C, after the resist pattern 104 is removed by ashing, a resist pattern 105 in which a part of the upper surface of the stacked body LMs is covered with the hard mask pattern 81 interposed therebetween, and the contact holes CL(9), CL(10), CL(13), and CL(14) are respectively exposed from the plurality of openings. In addition, the contact holes CL(9) and CL(13) exposed from the opening of the resist pattern 105 are caused to reach the insulating layer NL(5), and the contact holes CL(10) and CL(14) are caused to reach the insulating layer NL(3).

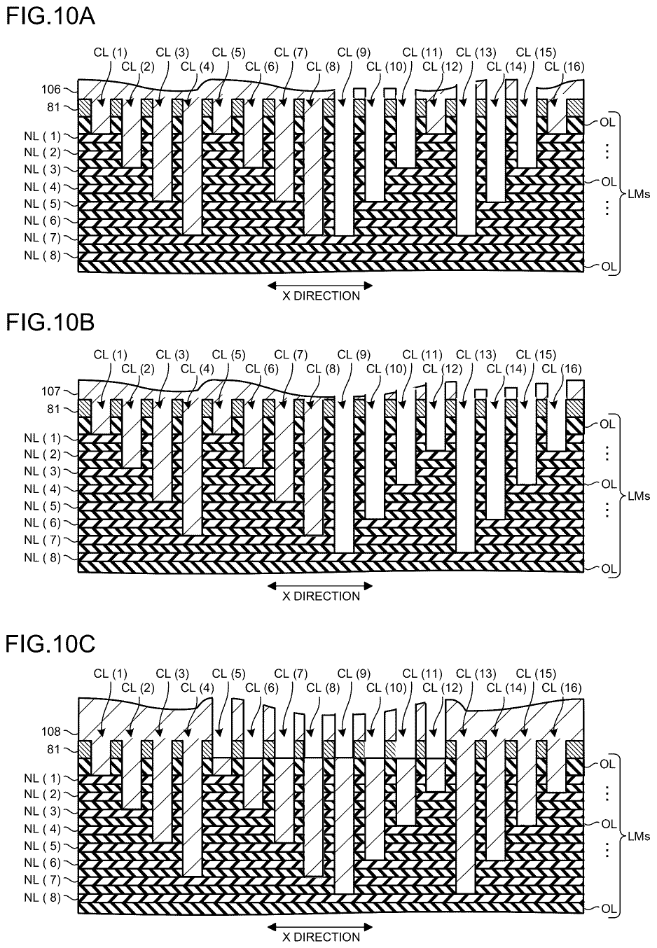

As illustrated in FIG. 10A, after the resist pattern 105 is removed by ashing, a resist pattern 106 in which a part of the upper surface of the stacked body LMs is covered with the hard mask pattern 81 interposed therebetween, and the contact holes CL(9), CL(10), CL(11), CL(13), CL(14), and CL(15) are respectively exposed from the plurality of openings is formed. In addition, the contact holes CL(9) and CL(13) exposed from the opening of the resist pattern 106 are caused to reach the insulating layer NL(7), the contact holes CL(10) and CL(14) are caused to reach the insulating layer NL(5), and the contact holes CL(11) and CL(15) are caused to reach the insulating layer NL(3).

As described above, the contact hole CL reaching the even-numbered insulating layer NL is also processed in the same manner as the contact hole CL reaching the odd-numbered insulating layer NL described above. However, in the contact hole CL reaching the even-numbered insulating layer NL, the following processing is performed one more time.

As illustrated in FIG. 10B, after the resist pattern 106 is removed by ashing, a part of the upper surface of the stacked body LMs is covered with the hard mask pattern 81 interposed therebetween, and the resist pattern 107 in which all the contact holes CL reaching the even-numbered insulating layers NL from the plurality of openings, that is, the contact holes CL(9) to CL(16) are exposed is formed.

In addition, the contact holes CL(9) to CL(16) exposed from the opening of the resist pattern 107 are caused to penetrate only one layer of the insulating layer NL, so that the contact holes CL(9) and CL(13) are caused to reach the insulating layer NL(8), the contact holes CL(10) and CL(14) are caused to reach the insulating layer NL(6), the contact holes CL(11) and CL(15) are caused to reach the insulating layer NL(4), and the contact holes CL(12) and CL(16) are caused to reach the insulating layer NL(2).

As described above, two sets of the contact holes CL(1) to CL(4) and the contact holes CL(5) to CL(8) that reach the odd-numbered insulating layers NL, that is, the insulating layers NL(1), NL(3), NL(5), and NL(7), respectively, are formed on the left side of the drawing. On the other hand, two sets of the contact holes CL(9) to CL(12) and the contact holes CL(13) to CL(16) that reach the even-numbered insulating layers NL, that is, the insulating layers NL(2), NL(4), NL(6), and NL(8), respectively, are formed on the right side of the drawing.

That is, the contact holes CL(1) to CL(8) on the left half of the drawing and the contact holes CL(9) to CL(16) on the right half of the drawing respectively reach the layers of the insulating layer NL, which are different by one layer therebetween.

Thereafter, as described below, among the two sets of the contact holes CL(1) to CL(4) and CL(5) to CL(8) reaching the insulating layer NL of the identical layer on the left half of the drawing, the contact holes CL(5) to CL(8) closer to the center of the drawing are additionally processed, and among the two sets of the contact holes CL(9) to CL(12) and CL(13) to CL(16) reaching the insulating layer NL of the same layer on the right half of the drawing, the contact holes CL(9) to CL(12) closer to the center of the drawing are additionally processed.

As illustrated in FIG. 10C, a resist pattern 108 for additionally processing the contact holes CL(5) to CL(12) at the center of the drawing is formed. FIG. 10C illustrates the resist pattern 108 directly after exposure and development.

The resist pattern 108 has an opening at a position overlapping the contact holes CL(5) to CL(12) by exposure and development. Further, the contact holes CL(5) to CL(12) are filled with a resist material that has not been removed by exposure and development.

As described above, since the resist material relatively flows into the contact holes CL(5) to CL(12) of the deep holes, the layer thickness of the resist pattern 108 is thinner at the position overlapping the contact holes CL(5) to CL(12) than the other portions.

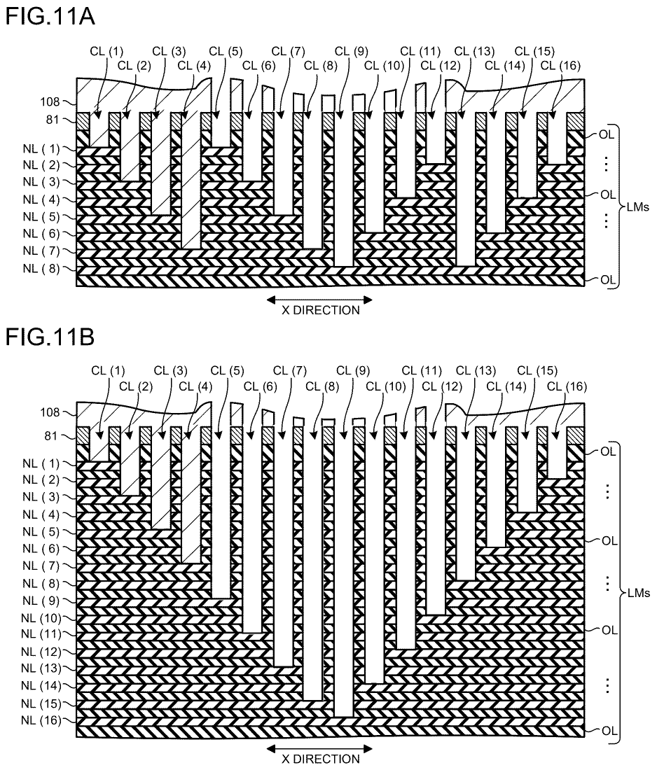

As illustrated in FIG. 11A, the resist material in the contact holes CL(5) to CL(12) is removed by entirely etching back the resist pattern 108. As a result, the layer thickness of the entire resist pattern 108 is further reduced.

As illustrated in FIG. 11B, the contact holes CL(5) to CL(12) exposed from the resist pattern 108 are etched to penetrate the eight insulating layers NL and reach the insulating layers NL below the insulating layers NL.

As a result, the contact holes CL(5) to CL(8) respectively reach the insulating layers NL below the contact holes CL(1) to CL(4) among the odd-numbered insulating layers NL. That is, the contact hole CL(5) reaches the insulating layer NL(9), the contact hole CL(6) reaches the insulating layer NL(11), the contact hole CL(7) reaches the insulating layer NL(13), and the contact hole CL(8) reaches the insulating layer NL(15).

In addition, the contact holes CL(9) to CL(12) respectively reach the insulating layers NL below the contact holes CL(13) to CL(16) among the even-numbered insulating layers NL. That is, the contact hole CL(9) reaches the insulating layer NL(16), the contact hole CL(10) reaches the insulating layer NL(14), the contact hole CL(11) reaches the insulating layer NL(12), and the contact hole CL(12) reaches the insulating layer NL(10).

As described above, the contact holes CL(1) to CL(8) that respectively reach the odd-numbered insulating layers NL, that is, the insulating layers NL(1), NL(3), NL(5), NL(7), NL(9), NL(11), NL(13), and NL(15) are formed on the left side of the drawing. On the other hand, on the right side of the drawing, the contact holes CL(9) to CL(16) that respectively reach the even-numbered insulating layers NL, that is, the insulating layers NL(2), NL(4), NL(6), NL(8), NL(10), NL(12), NL(14), and NL(16) are formed.

That is, the contact holes CL(1) to CL(8) on the left half of the drawing and the contact holes CL on the right half of the drawing respectively reach the layers of the insulating layer NL, which are different by one layer therebetween. As a result, any one of the 16 contact holes CL(1) to CL(16) reaches the insulating layers NL(1) to NL(16) of the 16 insulating layers.

Thereafter, the resist pattern 108 is removed by ashing using oxygen plasma or the like. In addition, the contact holes CL(1) to CL(16) are filled with a sacrificial layer such as an amorphous silicon layer or a CVD-carbon layer, and the insulating layer 56, the conductive layer 26 (refer to FIG. 2B and the like), and the like are formed in a later step to form a plurality of contacts CC.

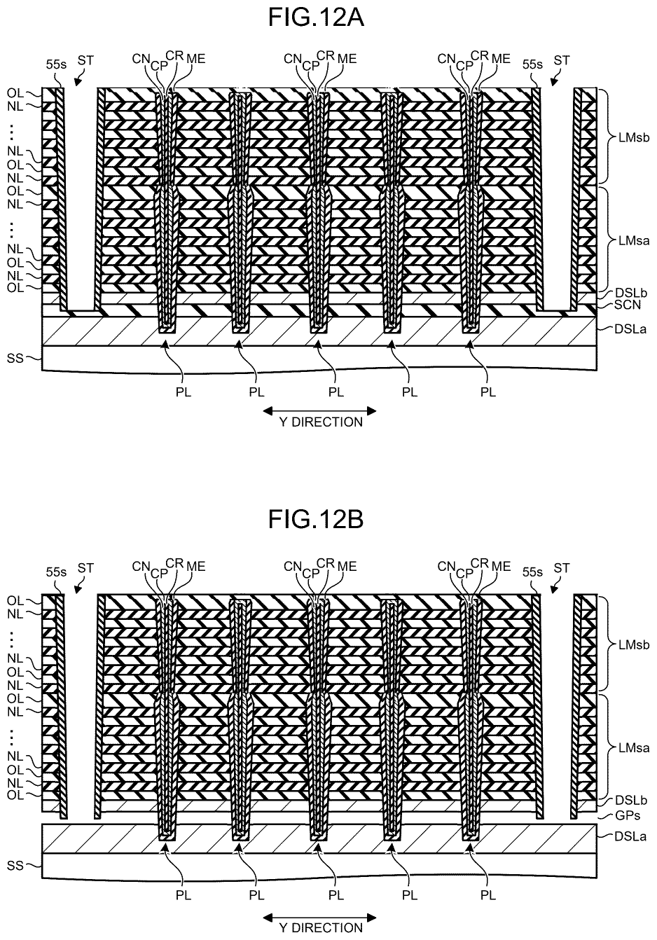

Next, FIGS. 12A to 15B illustrate a state in which the intermediate source line BSL is formed from the intermediate sacrificial layer SCN of the source line SL, and the word line WL and the like are formed from the insulating layers NL of the stacked bodies LMsa and LMsb. Similarly to FIGS. 3A to 6B described above, FIGS. 12A to 15B illustrate a cross section in the Y direction of the semiconductor memory device 1 in the middle of manufacturing, including a region to be the memory region MR later.

As illustrated in FIG. 12A, a slit ST that penetrates the stacked bodies LMsb and LMsa and the upper source line DSLb and reaches the intermediate sacrificial layer SCN is formed. Further, insulating layers 55s are respectively formed on the side walls of the slit ST, which face each other in the Y direction. The slit ST also extends in the X direction in the stacked bodies LMsa and LMsb.

As illustrated in FIG. 12B, a removing liquid of the intermediate sacrificial layer SCN such as thermal phosphoric acid is caused to flow through the slit ST, the side wall of which is protected by the insulating layer 55s, and the intermediate sacrificial layer SCN sandwiched between the lower source line DSLa and the upper source line DSLb is removed.

As a result, a gap layer GPs is formed between lower source line DSLa and upper source line DSLb. Further, a part of the memory layer ME in the outer peripheral portion of the pillar PL is exposed in the gap layer GPs. At this time, since the side wall of the slit ST is protected by the insulating layer 55s, the insulating layer NL in the stacked bodies LMsa and LMsb is suppressed from being removed.

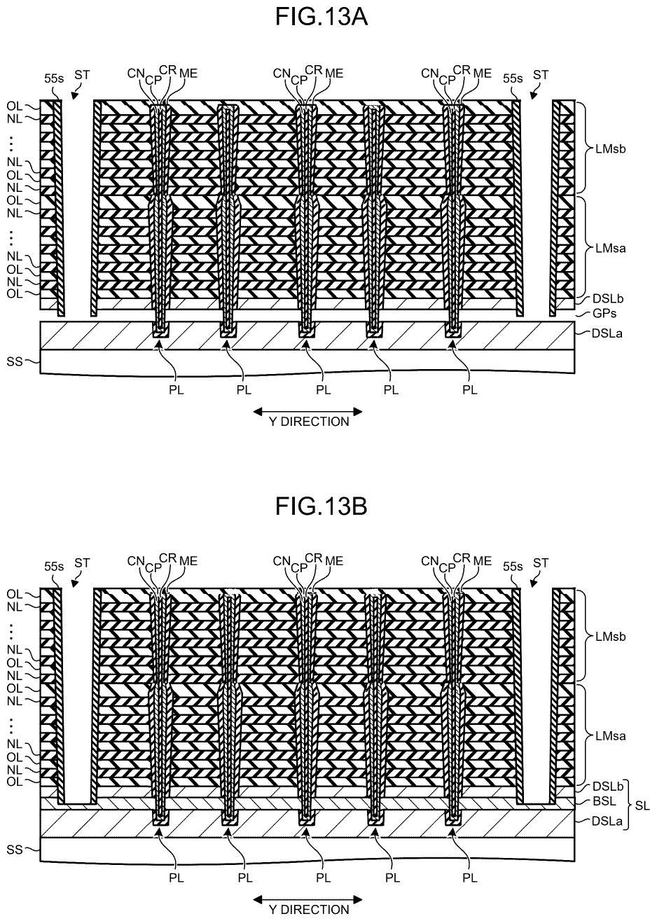

As illustrated in FIG. 13A, the chemical liquid is appropriately caused to flow into the gap layer GPs through the slit ST, and the block insulating layer, the charge storage layer, and the tunnel insulating layer (all not illustrated in the drawing) of the memory layer ME exposed in the gap layer GPs are sequentially removed. As a result, the memory layer ME is removed from a side wall of a part of the pillar PL, and a part of the channel layer CN on the inner side is exposed in the gap layer GPs.

As illustrated in FIG. 13B, a source gas such as amorphous silicon is injected from the slit ST, the side wall of which is protected by the insulating layer 55s, and the gap layer GPs is filled with amorphous silicon or the like. In addition, the support substrate SS is heat-treated to polycrystallize the amorphous silicon filling the gap layer GPs, thereby forming the intermediate source line BSL containing polysilicon or the like.

As a result, a part of the channel layer CN of the pillar PL is connected to the source line SL on the side surface via the intermediate source line BSL.

Although not illustrated in the drawing, the slit ST also extends to a region to be the contact region ER later, and the lower end portion of the slit ST reaches the intermediate insulating layer SCO sandwiched between the lower source line DSLa and the upper source line DSLb. Therefore, the intermediate insulating layer SCO is not affected through the processing in FIGS. 12A to 13B described above, and remains even after the processing in FIGS. 12A to 13B described above.

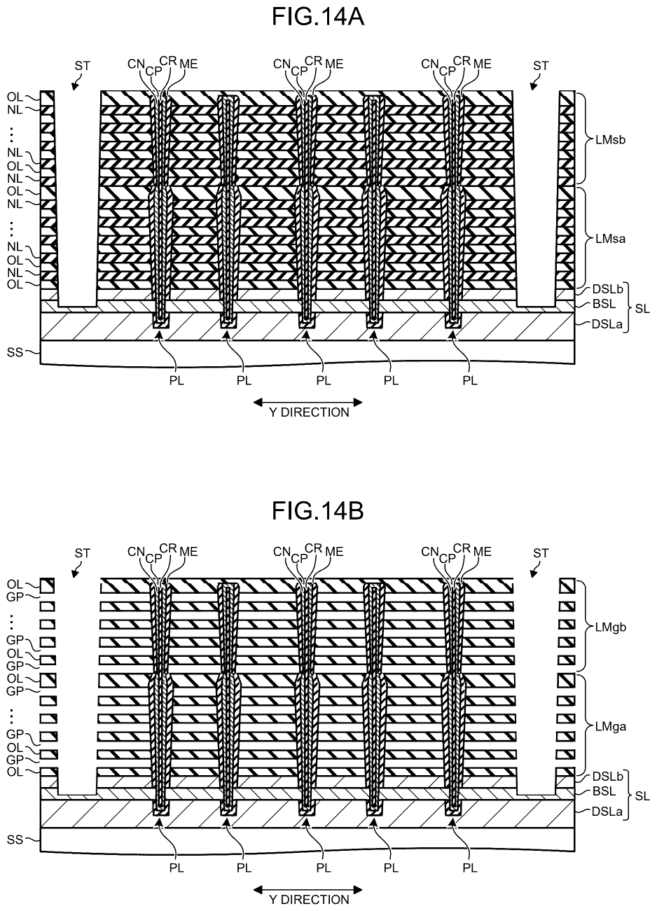

As illustrated in FIG. 14A, the insulating layer 55s on the side wall of the slit ST is removed.

As illustrated in FIG. 14B, a removing liquid of the insulating layer NL, such as thermal phosphoric acid, is caused to flow from the slit ST from which the insulating layer 55s has been removed into the stacked bodies LMsa and LMsb, and the insulating layers NL of the stacked bodies LMsa and LMsb are removed. As a result, stacked bodies LMga and LMgb having the plurality of gap layers GP from which the insulating layers NL disposed between the insulating layers OL are removed are formed.

The stacked bodies LMga and LMgb including the plurality of gap layers GP have a fragile structure. The plurality of pillars PL support such fragile stacked bodies LMga and LMgb. Although not illustrated in the drawing, in the contact region ER, the above-described columnar portion HR (refer to FIG. 2B and the like) supports the above-described fragile stacked bodies LMga and LMgb. As a result, bending of the insulating layer OL remaining in the stacked bodies LMga and LMgb and distortion or collapse of the stacked bodies LMga and LMgb are suppressed.

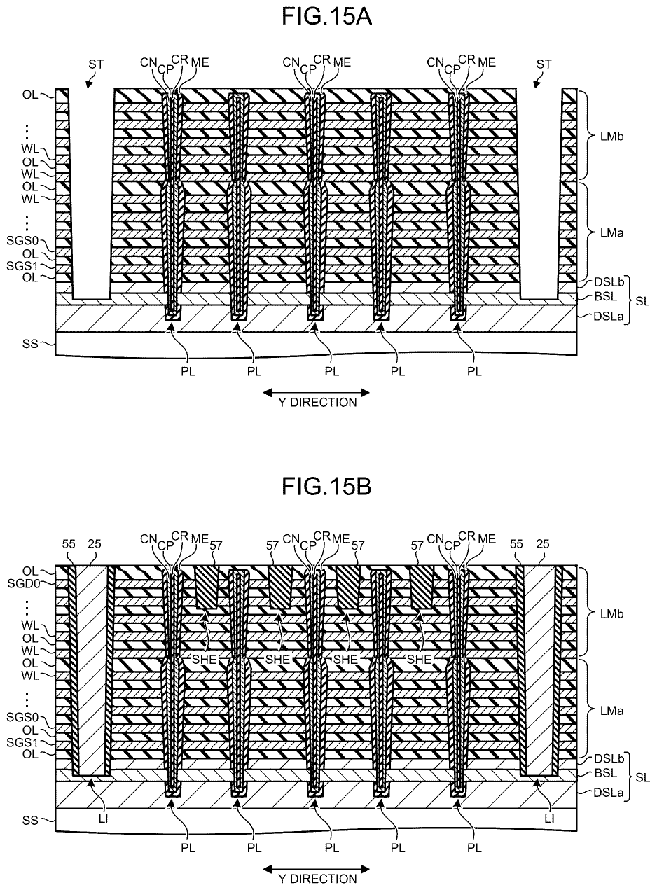

As illustrated in FIG. 15A, a source gas of a conductive material such as tungsten or molybdenum is injected from the slit ST into the stacked bodies LMga and LMgb, and the gap layers GP of the stacked bodies LMga and LMgb are filled with the conductive material to form the plurality of word lines WL and the like. As a result, the stacked body LM including the stacked bodies LMa and LMb in which the plurality of word lines WL and the like and the plurality of insulating layers OL are alternately stacked on each other is formed.

As described above, the processing of forming the intermediate source line BSL from the intermediate sacrificial layer SCN and the processing of forming the word line WL from the insulating layer NL are also referred to as replacement processing.

As illustrated in FIG. 15B, the conductive layer 25 fills the inside of the slit ST via the insulating layer 55 to form the plate-shaped contact LI. In addition, a groove penetrating one or a plurality of conductive layers including the conductive layer of the uppermost layer of the stacked body LMb is formed, and the insulating layer 57 fills the inside of the groove, thereby forming the separation layer SHE that partitions these conductive layers into the pattern of the select gate line SGD.

Thereafter, although not illustrated in the drawing, after the sacrificial layer is removed from the plurality of contact holes CL (refer to FIG. 11B and the like) formed in the contact region ER, the conductive layer 26 fills the inside of these contact holes CL via the insulating layer 56 to form a plurality of contacts CC connected to the plurality of word lines WL and the select gate lines SGD and SGS, respectively.

In addition, after the insulating layer 52 covering the stacked body LM is formed, the plug CH formed to penetrate the insulating layer OL of the uppermost layer and the insulating layer 52 of the stacked body LM and connected to the cap layer CP at the upper end portion of the pillar PL is formed. In addition, the insulating layer 53 covering the insulating layer 52 is formed, and the bit line BL to which each plug CH is connected is formed in the insulating layer 53.

In parallel with this, the plug V0 formed to penetrate the insulating layer 52 and connected to the upper end portion of the contact CC is formed. In addition, the upper layer wiring MX to which each plug V0 is connected is formed in the insulating layer 53.

For example, the plug CH and the bit line BL, and the plug V0 and the upper layer wiring MX may be collectively formed by using a dual damascene method or the like.

In addition, the peripheral circuit CBA is formed on the semiconductor substrate SB separate from the support substrate SS on which the stacked body LM is formed, and is covered with the insulating layer 40. In the insulating layer 40, a contact, a via, a wiring, or the like that leads the peripheral circuit CBA to the surface of the insulating layer 40 is formed and is connected to an electrode pad or the like formed on the upper surface of the insulating layer 40.

Subsequently, the support substrate SS and the semiconductor substrate SB are bonded to each other by the insulating layers 50 and 40, respectively, and the electrode pads in the insulating layers 50 and 40 are connected to each other. Thereafter, the support substrate SS is removed to expose the source line SL, and the electrode film EL is connected via the insulating layer 60 on which the plug PG is formed.

As described above, the semiconductor memory device 1 of the first embodiment is manufactured.

### Comparative Example

In a semiconductor memory device such as a three-dimensional nonvolatile memory, a plurality of contacts formed to penetrate a stacked body in which a plurality of word lines and the like are stacked and respectively connected to individual word lines and the like may be formed. The plurality of contacts are obtained by forming a resist pattern a plurality of times and forming a plurality of contact holes having different reaching depths.

However, when the resist pattern is formed on the contact holes during the formation of the plurality of contact holes, these contact holes are also filled with a resist material. At this time, since the filling amount of the resist material varies depending on the reaching depth of the contact hole, the layer thickness of the resist pattern may vary. As a result, variations occur in the exposed state of the resist pattern for each layer thickness, and variations also occur in the opening areas of the plurality of openings, or a non-opening portion occurs and the contact hole to be processed cannot be exposed.

Furthermore, when the resist material filling the inside of the contact hole is removed, the layer thickness of the entire resist pattern decreases, and there is a possibility that a portion not to be etched is not sufficiently protected by the subsequent additional etching of the contact hole.

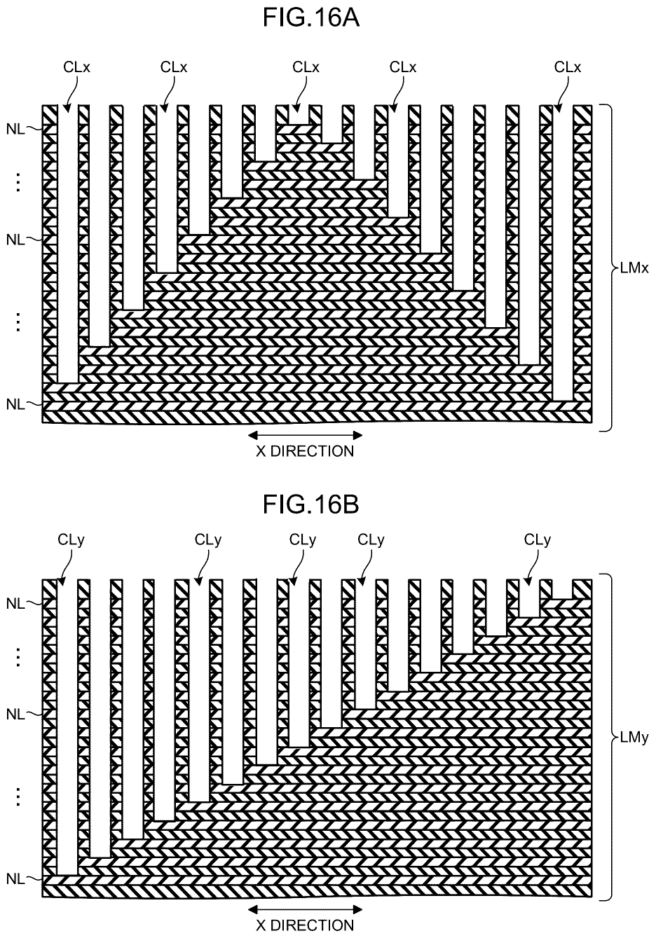

As a result of intensive studies, the present inventor has found that such variation in the layer thickness of the resist pattern can be suppressed by optimizing the arrangement order of the contact holes having different reaching depths. According to the present inventors, when there is a portion in which the reaching depth of the contact hole rapidly changes, the variation in the layer thickness of the resist pattern increases. More specifically, when the volume of the contact hole present per unit area rapidly changes between adjacent regions, the variation in the layer thickness of the resist pattern increases. FIGS. 16A and 16B illustrate some examples.

FIGS. 16A and 16B are cross-sectional views illustrating an example of the arrangement order of contact holes CLx and CLy according to the comparative example.

In the example illustrated in FIG. 16A, in the plurality of contact holes CLx extending in a stacked body LMx, the arrangement order of the contact holes CLx on the left and right sides with a central portion in the drawing sandwiched therebetween is opposite to that of the contact hole CL of the above-described first embodiment.

That is, the reaching depth of the plurality of contact holes CLx reaching the odd-numbered insulating layers NL on the left half of the drawing decreases from the left side of the drawing toward the plurality of contact holes CLx reaching the even-numbered insulating layers NL on the right half of the drawing. Similarly, the reaching depth of the plurality of contact holes CLx reaching the even-numbered insulating layers NL on the right half of the drawing decreases from the right side of the drawing toward the plurality of contact holes CLx reaching the odd-numbered insulating layers NL on the left half of the drawing.

In such an arrangement, on both sides in the X direction of the plurality of contact holes CLx, the volume of the contact hole CLx per unit area rapidly changes from a portion in which the contact hole CLx of a deep hole is formed to a portion in which the contact hole CLx is not formed outside a contact hole CLx arrangement region. As described above, in such an arrangement, the variation in the layer thickness of the resist pattern increases.

In the example illustrated in FIG. 16B, the reaching depth of the plurality of contact holes CLy extending in a stacked body LMy sequentially increases from the right side of the drawing to the left side of the drawing. Even in such an arrangement, on the left side in the X direction of the plurality of contact holes CLy, the volume of the contact hole CLy per unit area rapidly changes from a portion in which the contact hole CLy of a deep hole is formed to a portion in which the contact hole CLy is not formed outside a contact hole CLy arrangement region. As described above, even in such an arrangement, the variation in the layer thickness of the resist pattern increases.

As described above, in order to reduce the variation in the layer thickness of the resist pattern, it is desirable to arrange the contact holes in an arrangement order that avoids a rapid change in the reaching depth of the contact hole as much as possible and suppresses a rapid change in the volume of the contact hole per unit area.

According to the semiconductor memory device 1 of the first embodiment, the plurality of contacts CC are arranged side by side in the X direction, and are arranged such that the reaching depth increases from both end portions in the X direction toward the central portion. With such an arrangement order, when the contacts CC are formed, it is possible to avoid a rapid change in the reaching depth of the contact holes CL. Therefore, variations in the layer thickness of the resist pattern 108 and the like on the plurality of contact holes CL having different reaching depths can be suppressed.

### First Modification

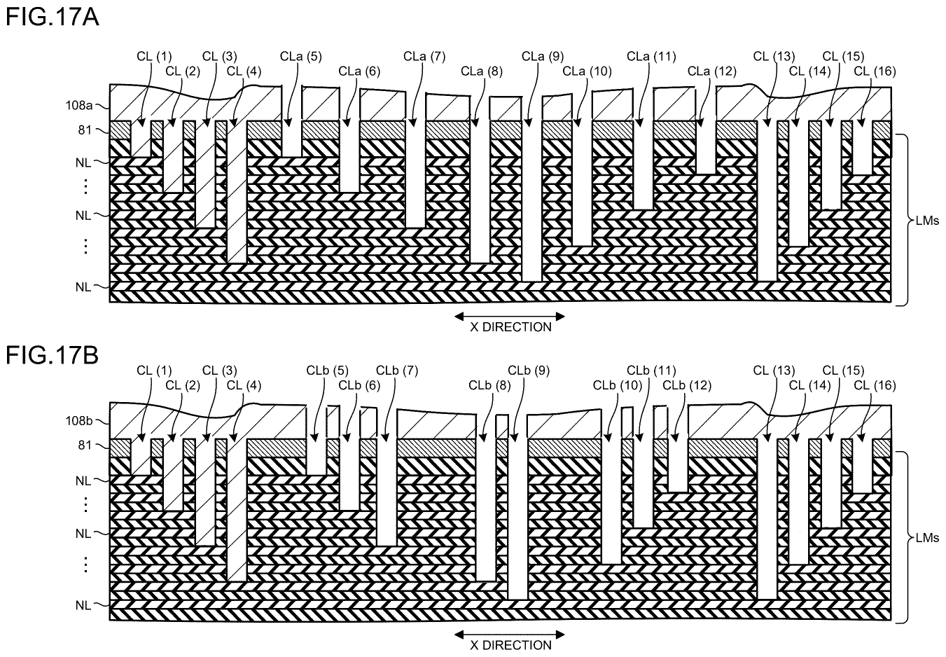

Next, a formation method of contact holes CL, CLa, and CLb in a semiconductor memory device according to a first modification of the first embodiment will be described with reference to FIGS. 17A and 17B. The semiconductor memory device of the first modification is different from that of the first embodiment in that the pitches of the plurality of contact holes CLa and CLb are changed.

FIGS. 17A and 17B are diagrams illustrating a part of a procedure of a manufacturing method of the semiconductor memory device according to the first modification of the first embodiment. FIGS. 17A and 17B illustrate a stage immediately before all the contact holes CL, CLa, and CLb reach a reaching target insulating layer NL, and are views corresponding to FIG. 11A of the first embodiment described above. This is because, among the formation processes of the contact holes CL, CLa, and CLb, which are repeatedly performed a plurality of times, the contact holes CLa and CLb to be processed in the final step are the deepest holes, and a layer thickness difference tends to be most significant in the resist pattern at this time.

It is noted that, in FIGS. 17A and 17B, the same reference numerals will be given to the same configurations as those of the above-described first embodiment, and the description thereof may be omitted.

In the example illustrated in FIG. 17A, among the plurality of contact holes CL(1) to CL(4), CLa(5) to CLa(12), and CL(13) to CL(16) arranged in order from the left side, the pitches of the contact holes CLa(5) to CLa(12) to be processed in the final step are made wider than those of the other contact holes CL(1) to CL(4) and CL(13) to CL(16).

At this time, the pitches of the contact holes CLa(5) to CLa(12) may be equal to or different from each other.

As described above, by widening the pitches of the contact holes CLa(5) to CLa(12) to be processed, which are the deepest holes, in advance at this final stage, the arrangement density of these contact holes CLa(5) to CLa(12) can be reduced, and the amount of the resist material flowing into the contact holes CLa(5) to CLa(12) per unit area can be reduced. Therefore, a layer thickness difference of the resist pattern 108a is reduced.

In the example illustrated in FIG. 17B, among the plurality of contact holes CL(1) to CL(4), CLb(5) to CLb(12), and CL(13) to CL(16) arranged in order from the left side, a blank region in which none of the contact holes CL and CLb is arranged is provided between the contact holes CLb(5) to CLb(12) to be processed in the final step. More specifically, the contact holes CLb(5) to CLb(12) are divided into a plurality of groups such as the contact holes CLb(5) to CLb(7), CLb(8) and CLb(9), and CLb(10) to CLb(12), and the blank region is arranged between the respective groups.

At this time, the pitches of the contact holes CLb(5) to CLb(7), the contact holes CLb(8) and CLb(9), and the contact holes CLb(10) to CLb(12) may be equal to or different from each other. In addition, the pitches between the respective groups may be equal to or different from each other.

In such a configuration as well, the arrangement density of these contact holes CLb(5) to CLb(12) can be reduced, and the amount of the resist material flowing into the contact holes CLb(5) to CLb(12) per unit area can be reduced. Therefore, a layer thickness difference of a resist pattern 108b is reduced.

The semiconductor memory device of the first modification includes the contact CC formed of the following plurality of contact holes CL, CLa, and CLb. That is, among the plurality of contact holes CL, CLa, and CLb, an average value of the pitches between the plurality of contact holes CLa and CLb, the reaching depth of which is equal to or larger than the depth of the insulating layer NL(9), is larger than the average value of the pitches between the plurality of contact holes CL, the reaching depth of which is less than the depth of the insulating layer NL(9).

As a result, it is possible to suppress variations in the layer thicknesses of the resist patterns 108a and 108b on the plurality of contact holes CL, CLa, and CLb having different reaching depths.

The semiconductor memory device of the first modification includes the contact CC formed of the following plurality of contact holes CL and CLa. That is, the pitches of the plurality of contact holes CLa, the reaching depth of which is equal to or larger than the depth of the insulating layer NL(9), are equal.

In such a configuration as well, it is possible to suppress variations in the layer thickness of the resist pattern 108a on the plurality of contact holes CL and CLa having different reaching depths.

The semiconductor memory device of the first modification includes the contact CC formed of the following plurality of contact holes CL and CLb. That is, a region in which the plurality of contact holes CLb each having a reaching depth equal to or larger than the depth of the insulating layer NL(9) are arranged has a blank region in which none of the plurality of contact holes CL and CLb is arranged.

In such a configuration as well, it is possible to suppress variations in the layer thickness of the resist pattern 108b on the plurality of contact holes CL and CLb having different reaching depths.

According to the semiconductor memory device of the first modification, other effects similar to those of the semiconductor memory device 1 of the first embodiment described above are obtained.

### Second Modification

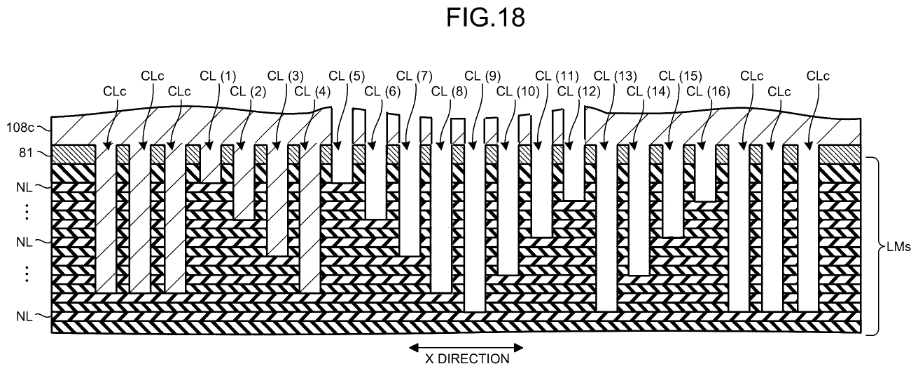

Next, a formation method of contact holes CL and CLc in a semiconductor memory device according to a second modification of the first embodiment will be described with reference to FIG. 18. The semiconductor memory device of the second modification is different from that of the first embodiment in that a dummy contact hole CLc is added.

FIG. 18 is a diagram illustrating a part of a procedure of a manufacturing method of the semiconductor memory device according to the second modification of the first embodiment. FIG. 18 illustrates a stage immediately before all the contact holes CL reach the reaching target insulating layer NL, and is a diagram corresponding to FIG. 11A of the first embodiment described above.

It is noted that, in FIG. 18, the same reference numerals will be given to the same configurations as those of the above-described the first embodiment, and the description thereof may be omitted.

As illustrated in FIG. 18, in the second modification, the dummy contact hole CLc having a predetermined reaching depth is added on the further outer side in the X direction of the plurality of contact holes CL(1) to CL(16) arranged in order from the left side. The number and reaching depth of the contact holes CLc to be added are arbitrary.

However, in order to avoid an increase in the number of steps, the contact hole CLc is preferably formed in parallel with any of the other contact holes CL(1) to CL(16), and the reaching depth is preferably determined in accordance with the contact hole CL of a relatively deep hole among these contact holes CL(1) to CL(16). In addition, the number of contact holes CLc to be added can be adjusted so that a layer thickness difference of a resist pattern 108c used in the final step is reduced as much as possible.

As a result, it is possible to further suppress a rapid change in volume of the contact hole CL per unit area from a portion in which the plurality of contact holes CL are formed to a portion in which the contact hole CL is not formed outside a contact hole CL arrangement region at both end portions in the X direction of the plurality of contact holes CL.

The semiconductor memory device of the second modification includes the contact CC formed of the following plurality of contact holes CL and CLc. That is, the dummy contact holes CLc each having a reaching depth equal to or larger than a predetermined depth are arranged outside both end portions in the X direction of the arrangement region of the plurality of contact holes CL.

In such a configuration as well, it is possible to suppress variations in the layer thickness of the resist pattern 108c on the plurality of contact holes CL having different reaching depths.

According to the semiconductor memory device of the second modification, other effects similar to those of the semiconductor memory device 1 of the first embodiment described above are obtained.

### Third Modification

In the second modification, the dummy contact hole CLc is added to both end portions in the X direction of the contact hole CL, but a dummy contact hole may be added to both end portions in the Y direction as viewed in the entire semiconductor memory device.

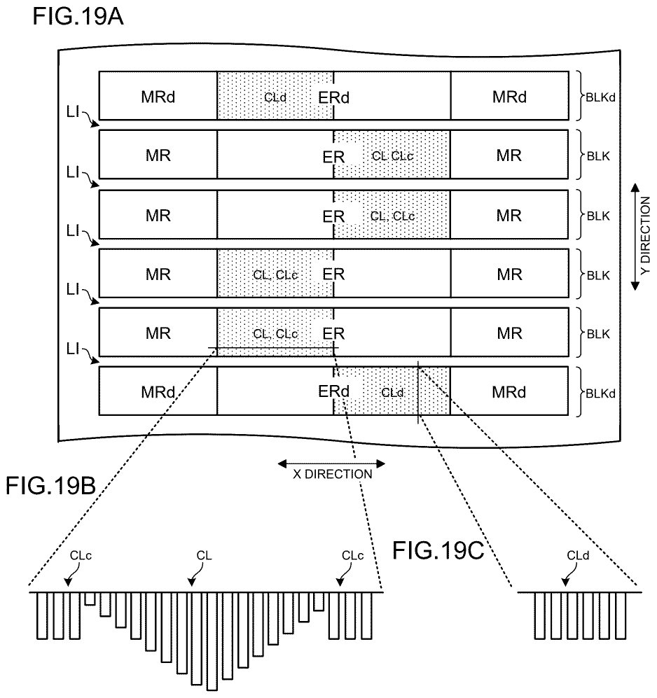

FIGS. 19A to 19C are schematic diagrams illustrating layouts in the process of manufacturing a semiconductor memory device according to a third modification of the first embodiment. More specifically, FIG. 19A is a plan view of the semiconductor memory device of the third modification, FIG. 19B is a cross-sectional view of the semiconductor memory device of the third modification in the X direction, and FIG. 19C is a cross-sectional view of the semiconductor memory device of the third modification in the Y direction.

It is noted that, in FIGS. 19A to 19C, the same reference numerals will be given to the same configurations as those of the first embodiment and the second modification described above, and the description thereof may be omitted.

As illustrated in FIGS. 19A and 19C, in the semiconductor memory device of the third modification, a dummy contact hole CLd having a predetermined reaching depth is formed in a dummy contact region ERd included in a dummy block region BLKd at both end portions in the Y direction.

As a result, it is possible to further suppress a rapid change in the volume of the contact hole CL per unit area over the entire plurality of contact regions ER and ERd arranged in the Y direction.

As illustrated in FIGS. 19A and 19B, in addition to the above-described configuration, the dummy contact holes CLc may also be added to both end portions in the X direction in each contact region ER as in the second modification.

The semiconductor memory device of the third modification includes the contact CC formed of the following plurality of contact holes CL and CLd. That is, dummy contact holes CLd each having a reaching depth equal to or larger than a predetermined depth are arranged outside both end portions in the Y direction of the arrangement region of the plurality of contact holes CL.

In such a configuration as well, it is possible to suppress variations in the layer thickness of the resist pattern on the plurality of contact holes CL having different reaching depths.

According to the semiconductor memory device of the third modification, other effects similar to those of the semiconductor memory device 1 of the first embodiment described above are obtained.

### Other Modifications

In the first embodiment and the first to third modifications described above, the contact region ER and the like are arranged in the central portion in the X direction of the stacked body LM. However, the arrangement position of the contact region in the stacked body LM is not limited thereto. The contact regions may be arranged, for example, at both end portions in the X direction of the stacked body LM, and in this case, for example, the memory region can be arranged at the central portion of the stacked body LM.

In the first embodiment and the first to third modifications described above, the pillar PL is connected to the source line SL on the side surface of the channel layer CN, but the present embodiment is not limited thereto. For example, the pillar may be configured to be connected to a source line at the lower end portion of a channel layer by removing a memory layer on the bottom surface of a pillar.

In addition, in the first embodiment and the first to third modifications described above, the insulating layers NL and OL are stacked in two portions, and the stacked body LM having a two-tier structure including the stacked bodies LMa and LMb is provided. However, the stacked body may have a one-tier structure or a structure of three tiers or more. By increasing the number of tiers, the number of stacked word lines WL can be further increased.

### Second Embodiment

Hereinafter, a second embodiment will be described in detail with reference to the drawings.

In the first embodiment described above, a description has been given as to a configuration in which the reaching depth of the contact holes CL arranged in the X direction increases toward the central portion in the X direction as the arrangement for reducing a layer thickness difference of the resist pattern 108 and the like.

At this time, a method in which the reaching depth is made different between about half and the remaining half of the plurality of contact holes CL arranged in the X direction in advance, and the reaching depth is increased by repeated processing is adopted. In such a method, it can be said that the arrangement order of the contact holes CL described above is appropriate.

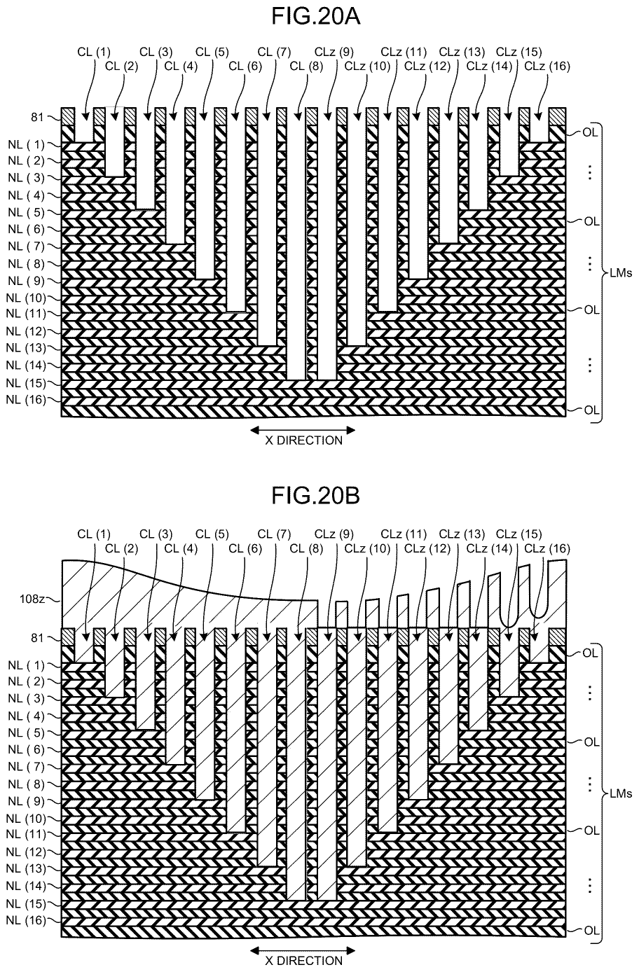

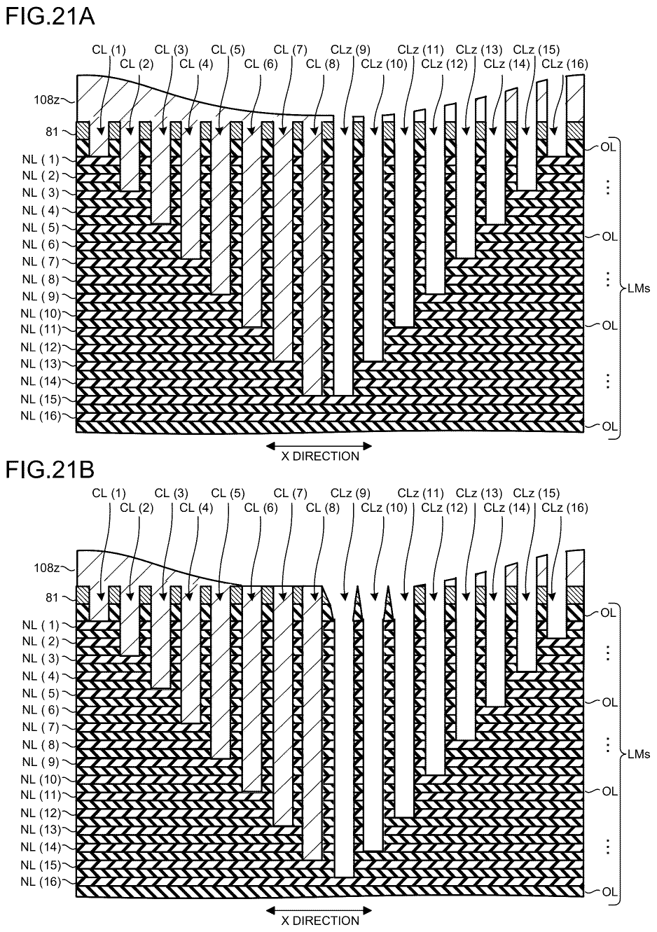

However, there are various methods of forming contact holes having different reaching depths, and an appropriate arrangement order of the contact holes may vary depending on these methods. As an example, FIGS. 20A to 21B illustrate a method in which about half and the remaining half of the plurality of contact holes arranged in the X direction are formed to have the same reaching depth, and the reaching depths are made different in the final stage.

FIGS. 20A and 21B are diagrams illustrating a part of a procedure of a manufacturing method of the semiconductor memory device according to the comparative example. Among FIGS. 20A to 21B, FIGS. 20A and 20B are diagrams each illustrating a stage immediately before all the contact holes CL and CLz reach the reaching target insulating layer NL.

As illustrated in FIG. 20A, the contact holes CLz(9) to CLz(16) on the right half of the drawing, which finally reach the even-numbered insulating layers NL, have a line-symmetric configuration with the contact holes CL(1) to CL(8) in the left half of the drawing, which have already reached the odd-numbered insulating layers NL as the final target, with the central portion of the drawing interposed therebetween. That is, the contact holes CLz(9) to CLz(16) respectively reach the insulating layers NL(15), NL(13), NL(11), NL(9), NL(7), NL(5), NL(3), and NL(1) in the same layer as the corresponding contact holes CL(8) to CL(1).

As described above, in the semiconductor memory device of the comparative example, for example, until directly before the final stage of the formation of the contact holes CL and CLz, the processes are performed in parallel so that the contact holes CL(1) to CL(8) and the contact holes CLz(9) to CLz(16) have the same configuration. Further, the contact holes CLz(9) to CLz(16) are additionally processed so as to reach the insulating layer NL one more layer below.

As illustrated in FIG. 20B, a resist pattern 108z for additionally processing the contact holes CLz(9) to CLz(16) is formed. FIG. 20B illustrates the resist pattern 108z directly after exposure and development.

The resist pattern 108z has an opening at positions respectively overlapping the contact holes CLz(9) to CLz(16) by exposure and development. In addition, the contact holes CLz(9) to CLz(16) are filled with a resist material that has not been removed by exposure and development.

Furthermore, in the configuration of the comparative example, it is necessary to provide an opening over the entire range from the shallowest hole to the deepest hole of the contact holes CLz(9) to CLz(16). This corresponds to a range including the thinnest portion to the thickest portion of the resist pattern 108z. For this reason, it is difficult to adjust the focus position at the time of exposure, and for example, when exposure is performed in accordance with the position above the contact hole CLz(9) in which the resist pattern 108z is the thinnest, there is a case in which the resist pattern 108z is not opened at the position above the contact hole CLz(19) in which the resist pattern 108z is the thickest.

As illustrated in FIG. 21A, in the above state, in order to remove the resist material in the contact holes CLz(9) to CLz(16), it is necessary to perform etch-back or the like on the entire surface of the resist pattern 108z for a longer time. Therefore, after the resist material is removed from the inside of the contact holes CLz(9) to CLz(16), the layer thickness of the resist pattern 108z is significantly reduced.

As illustrated in FIG. 21B, the contact holes CLz(9) to CLz(16) are additionally processed, and the contact holes CLz(9) to CLz(16) are caused to reach the even-numbered insulating layers NL(16), NL(14), NL(12), NL(10), NL(8), NL(6), NL(4), and NL(2) which are one layer lower.

However, as described above, for example, when the reduction amount of the layer thickness of the resist pattern 108z is large, the resist pattern 108z in a portion where the layer thickness was originally thin disappears, and the function as the mask may be partially impaired. In the example of FIG. 21B, the hard mask pattern 81 such as the contact holes CLz(9) to CLz(11), the insulating layer OL of the uppermost layer of the stacked body LMs, and the like are etched, and the opening portions of the contact holes CLz(9) to CLz(11) and the like are enlarged in diameter.

As described above, the arrangement of the contact holes of the first embodiment may not be necessarily appropriate in a case in which the formation methods of these contact holes are different.

Therefore, in order to properly arrange the contact holes having different reaching depths from each other, it is necessary to consider the number of layers such as word lines included in the semiconductor memory device, that is, the number of necessary contact holes, other design restrictions, and the like, in addition to the formation methods of these contact holes.

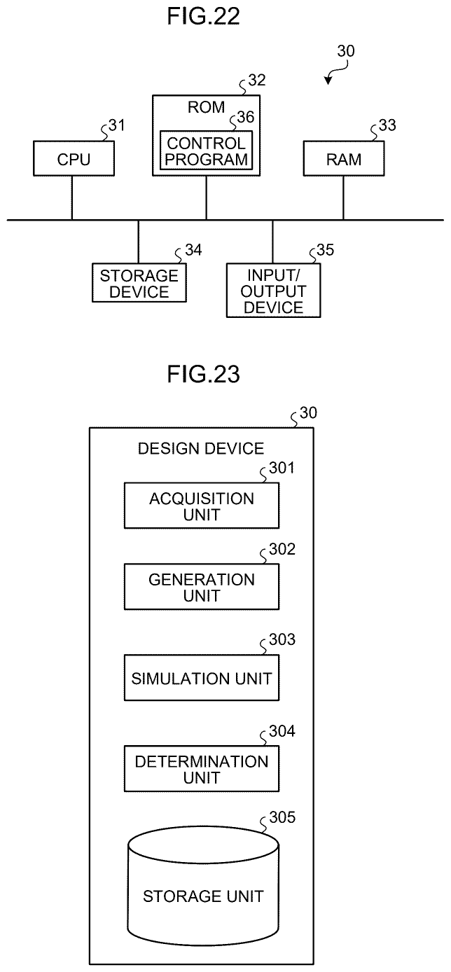

In the second embodiment, a design device 30 that optimizes the arrangement of contact holes having different reaching depths will be described with reference to FIGS. 22 to 26.

### Configuration Example of Design Device

FIG. 22 is a block diagram illustrating an example of a physical configuration of the design device 30 according to the second embodiment.

As illustrated in FIG. 22, the design device 30 of the second embodiment is configured as a computer including a central processing unit (CPU) 31, a read only memory (ROM) 32, a random access memory (RAM) 33, and a storage device 34.

The CPU 31 controls the entire design device 30. The ROM 32 functions as a storage region in the design device 30. The information stored in the ROM 32 is stored even when the power supply of the design device 30 is turned off. The RAM 33 functions as a primary storage device and serves as a working region for the CPU 31. The storage device 34 is an HDD, an SSD, or the like, and functions as an auxiliary storage device of the CPU 31.

It is noted that the design device 30 may include an input/output device 35 such as a keyboard, a mouse, and a display. The input/output device 35 is configured such that a user can input information, commands, and the like to the design device 30 and receive presentation of information from the design device 30 as a human machine interface (HMI) between the design device 30 and the user.

Further, a control program 36 executed by the CPU 31 may be stored in the ROM 32 or the like of the design device 30. The control program 36 can be provided by being recorded in various computer-readable recording media such as a flexible disk, a compact disc-recordable (CD-R), a digital versatile disk (DVD), a Blu-ray (registered trademark) disk, and a semiconductor memory.

Furthermore, the control program 36 may be configured to be stored in a computer connected to a network such as the Internet and may be provided by being downloaded via the network. Further, the control program 36 may be provided or distributed via a network such as the Internet.

FIG. 23 is a block diagram illustrating an example of a functional configuration of the design device 30 according to the second embodiment. As illustrated in FIG. 23, the above-described CPU 31 loads the control program 36 stored in the ROM 32 or the like in the RAM 33 and executes the control program, thereby implementing an acquisition unit 301, a generation unit 302, a simulation unit 303, a determination unit 304, and a storage unit 305 as respective functional units.

However, a part or all of the functional configuration of the design device 30 may be realized by a dedicated application specific integrated circuit (ASIC).

The acquisition unit 301 acquires design information on a contact hole to be optimized. The design information includes the number of stacked word lines and the like in the semiconductor memory device having the contact hole, the layout of the semiconductor memory device including a contact region, a memory region, and the like, design restrictions in arranging the contact hole, a resist pattern at the time of forming the contact hole, more strictly, an upper limit value of a layer thickness difference of a resist layer before exposure and development, and the like.

These pieces of design information may be input by the user from the input/output device 35 described above, or may be acquired from a higher-level design device or the like for designing the entire semiconductor memory device.

The generation unit 302 generates a predetermined arrangement of the contact holes on the basis of various types of design information acquired by the acquisition unit 301.

In the arrangement of the contact holes generated by the generation unit 302, the simulation unit 303 simulates a layer thickness difference to be included in the resist layer when the resist layer is formed on these contact holes.

The determination unit 304 determines whether the arrangement of the contact holes generated by the generation unit 302 satisfies various design restrictions. In addition, the determination unit 304 determines whether the layer thickness difference of the resist layer is within the upper limit value in the predetermined arrangement on the basis of the simulation result of the simulation unit 303.

The storage unit 305 stores various control parameters, control programs, and the like necessary for the operation of the design device 30. Furthermore, the storage unit 305 may store various types of design information acquired by the acquisition unit 301, various arrangements generated by the generation unit 302, various simulation results performed by the simulation unit 303, and the like.

### Operation Example of Design Device

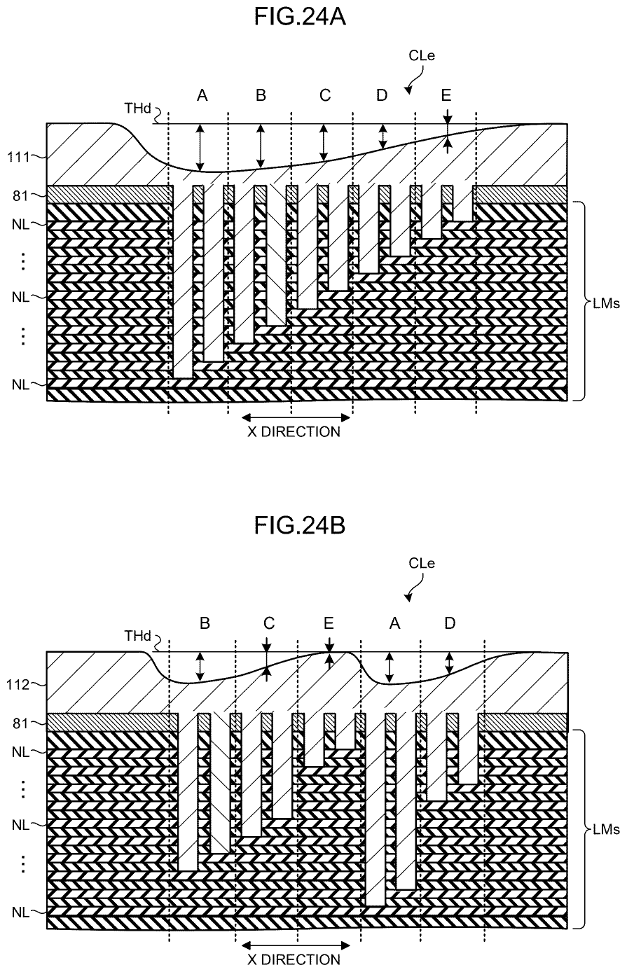

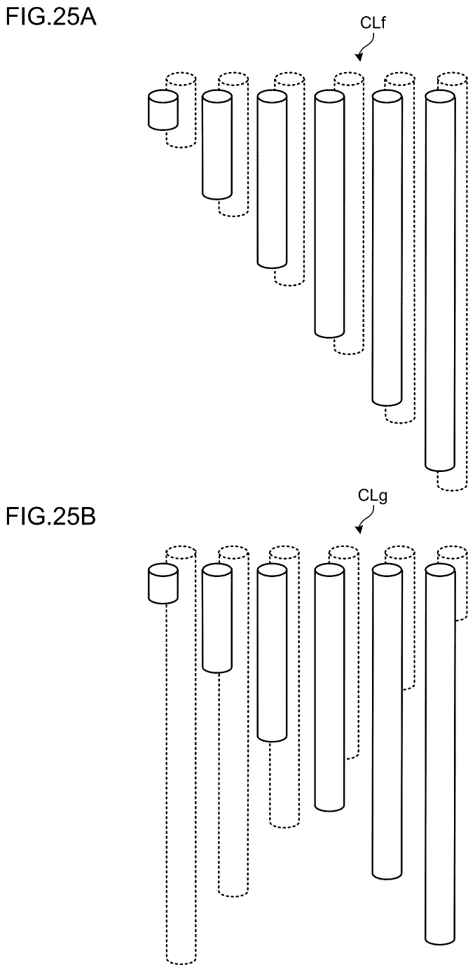

Next, an operation example of the design device 30 of the second embodiment will be described with reference to FIGS. 24A to 25B.

FIGS. 24A and 24B are schematic diagrams illustrating an example of the design operation of the arrangement of the contact holes CLe by the design device 30 according to the second embodiment.

The acquisition unit 301 of the design device 30 acquires design information of a target semiconductor memory device when designing the arrangement of contact holes of a predetermined semiconductor memory device.

The generation unit 302 generates an initial arrangement of the contact holes based on the design information acquired by the acquisition unit 301. For example, in a case where the design information indicates that the semiconductor memory device has 10 layers of word lines and select gate lines, it is understood that 10 contact holes having different reaching depths are required.

As illustrated in FIG. 24A, the generation unit 302 arranges these 10 contact holes CLe in an arbitrary arrangement order. The arbitrary arrangement order of the contact holes CLe may be an arrangement order in which the reaching depths sequentially increase from one side to the other side in the X direction, as in the example illustrated in FIG. 24A, or can be selected from various arrangement orders such as an arrangement order in which the contact holes CLe having different reaching depths are randomly arranged. A template of several arrangement orders may be prepared in advance, and an arrangement having a predetermined arrangement order may be selected from the template.

The determination unit 304 determines whether the initial arrangement of the contact holes CLe generated by the generation unit 302 satisfies various design restrictions with reference to the design information acquired by the acquisition unit 301.

Design restrictions include, for example, arrangement restrictions that occur in at least some contacts due to a word line or the like to be connected. As an example, there is a restriction that the contacts connected to the upper or lower select gate lines must be adjacent to each other. In addition, a predetermined function may be imparted to some word lines, and contacts connected to these word lines may also be required to be adjacent to each other.

Alternatively, contacts may be divided into several groups according to a hierarchy such as a word line to be connected, such as a high layer, a middle layer, and a low layer. In this case as well, a group of contacts belonging to the same group may be required to be adjacent to each other. Further, there may be a case in which there is a restriction that a blank region where no contact is arranged needs to be arranged between these groups.

In addition, in the contact region, there may be a restriction that it is necessary to dispersedly arrange every predetermined number of contacts. In this case as well, it is necessary to divide these contacts into a plurality of groups and to arrange a blank region between the individual groups.

Furthermore, in a case where contacts are divided into a plurality of groups, there is a case in which the arrangement order of the contacts in the group is restricted depending on a word line to be connected or the like, such as an odd-numbered one or an even-numbered one.

Furthermore, since wirings finally reaching the peripheral circuits are connected to the individual contacts, there may be a restriction that it is necessary to secure these wiring paths.

In a case in which the initial arrangement of the contact holes CLe generated by the generation unit 302 satisfies various restrictions, the simulation unit 303 simulates a layer thickness difference in a case in which the resist layer 111 is formed on the contact holes CLe having the initial arrangement. As described above, the resist layer 111 is in a state before exposure and development of a resist pattern to be used when the contact hole CLe is additionally processed.

The determination unit 304 determines whether the layer thickness difference of the resist layer 111 simulated by the simulation unit 303 is within the upper limit value with reference to the design information acquired by the acquisition unit 301.

When the initial arrangement of the contact holes CLe does not satisfy any of the restrictions or when the layer thickness difference of the resist layer 111 obtained by the simulation exceeds the upper limit value, the generation unit 302 changes the arrangement of the contact holes CLe so as to satisfy these conditions. Various methods can be considered for changing the arrangement of the contact holes CLe. The generation unit 302 can select a predetermined method from these various change methods.

Hereinafter, as an example, a case in which the arrangement of the contact holes CLe is changed on the basis of the layer thickness difference of the resist layer 111 for each of the regions A to E will be described.

In the example of FIG. 24A, it is assumed that the initial arrangement of the contact holes CLe satisfies the design restriction, but the layer thickness difference of the resist layer 111 obtained by the simulation exceeds the upper limit value. In this case, the generation unit 302 divides a region in which the contact holes CLe are disposed into several regions A to E, and compares the layer thickness of the resist layer 111 in each of the regions A to E with a layer thickness THd of a design value. As a result, a difference from the design value of the resist layer 111 in each of the regions A to E is obtained.

As illustrated in FIG. 24B, the generation unit 302 rearranges the arrangement order of the contact holes CLe to generate a new arrangement of the contact holes CLe so as to reduce the deviation of a difference from the design value of the resist layer 111 in each of the regions A to E.

In the example of FIG. 24B, it is assumed that the difference from the design value of the resist layer 111 in each of the regions A to E is the region A>B>C>D>E. That is, in the initial arrangement of the contact holes CLe, as the reaching depth of the contact hole CLe increases, the deviation of the layer thickness difference of the resist layer 111 increases. Therefore, the generation unit 302 replaces the arrangement order of the contact holes CLe, for example, and generates a new arrangement of the contact holes CLe so as to form the resist layer 112 having a small deviation in layer thickness difference, such as the region B>C>E<A<D.

It is noted that the method in the case of generating a new arrangement of the contact holes CLe so as to reduce the deviation of the difference from the design value of the resist layer 111 in each of the regions A to E is not limited to the above description. As an example, it is possible to use a method of quantifying the change in the layer thickness of the resist layer 111 using a moving average or the like and then changing the arrangement order of the contact holes CLe.

The determination unit 304 also determines whether the arrangement of the newly generated contact hole CLe satisfies various design restrictions. Furthermore, the simulation unit 303 simulates a layer thickness difference in a case in which the resist layer 112 is formed for the new arrangement.

The design device 30 repeats the above operation for these contact holes CLe until various design restrictions are satisfied and an arrangement in which the layer thickness difference of the resist layer is equal to or less than the upper limit value is obtained.

In addition, as described above, the contact hole of the semiconductor memory device is additionally processed a plurality of times until the reaching depth reaches the reaching target insulating layer NL. At that time, since the reaching depth of each contact hole changes from moment to moment, there is a possibility that the layer thickness difference of the resist layer formed above each contact hole is also different for each step. Therefore, the design device 30 considers whether the layer thickness difference of the resist layer is equal to or less than the upper limit value also in other steps for the proper arrangement of the contact hole obtained in one step.

In all the steps, when the arrangement in which the layer thickness difference of the resist layer is equal to or less than the upper limit value is obtained, the operation of the design device 30 is terminated.

It is noted that, in the initial arrangement of the contact holes or the rearrangement of the contact holes after the change, the design device 30 may adjust the number of contact hole arrangements and may perform other adjustments. When a plurality of contact holes are arranged, various variations can be further selected. FIGS. 25A and 25B illustrate some examples.

FIGS. 25A and 25B are schematic diagrams illustrating a variation example of the arrangement of contact holes CLf and CLg by the design device 30 according to the second embodiment.

FIG. 25A illustrates an example in which the reaching depths of the contact holes CLf are aligned among a plurality of arrangements.

FIG. 25B illustrates an example of a case in which the increase and decrease of the reaching depth are interchanged among a plurality of arrangements in a case in which the reaching depth of the contact hole CLg increases from one direction to the other direction.

### Processing Example of Design Device

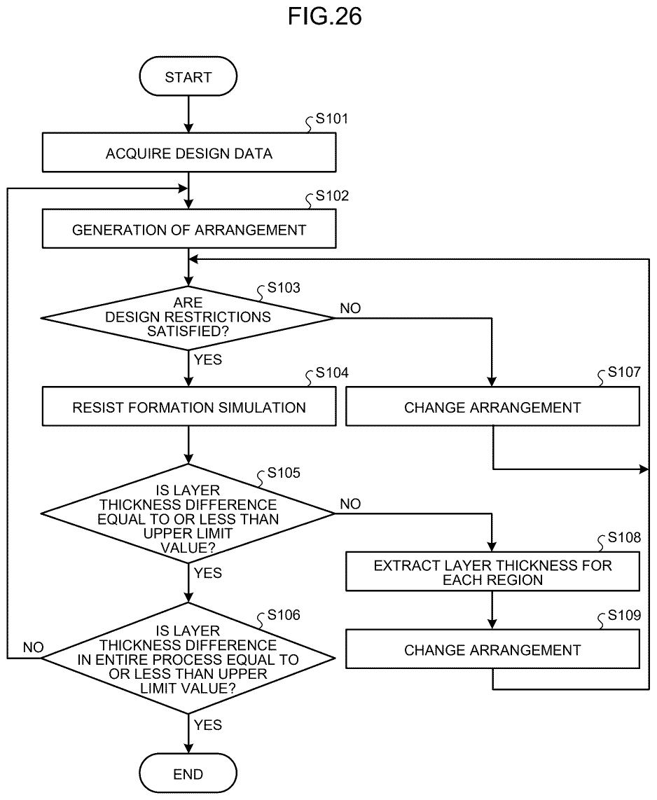

Next, a processing example in the design device 30 of the second embodiment will be described with reference to FIG. 26. FIG. 26 is a flowchart illustrating an example of a procedure of design processing of the contact hole arrangement by the design device 30 according to the second embodiment.

As illustrated in FIG. 26, the acquisition unit 301 of the design device 30 acquires design information of the semiconductor memory device as a processing target (step S101). The generation unit 302 generates an initial arrangement of the contact holes on the basis of the design information (step S102). The determination unit 304 determines whether the arrangement satisfies design restrictions (step S103).

When the generated arrangement of the contact holes does not satisfy any one of the design restrictions (step S103: No), the arrangement is changed to satisfy the restriction (step S107), and the processing from step S103 is repeatedly performed.

When the arrangement of the contact holes generated by the generation unit 302 satisfies the design restrictions (step S103: Yes), the simulation unit 303 simulates a layer thickness difference of a resist layer formed on these contact holes (step S104). The determination unit 304 determines whether a simulated layer thickness difference of the resist layer is equal to or less than the upper limit value (step S105).

In the generated arrangement of the contact holes, when the layer thickness difference of the resist layer exceeds the upper limit value (step S105: No), the layer thickness for each region is extracted (step S108), the arrangement is changed so that a layer thickness difference for each region of the resist layer is reduced (step S109), and the processing from step S103 is repeatedly performed.

If the layer thickness difference of the resist layer is equal to or less than the upper limit value (step S105: Yes), the determination unit 304 determines whether a resist layer before exposure and development of a resist pattern is equal to or less than a predetermined upper limit value in the entire process necessary for formation of the target contact hole (step S106).

When there is a step in which the resist layer exceeds the predetermined upper limit value (step S106: No), the processing from step S102 is repeatedly performed.

When the resist layer is equal to or less than the predetermined upper limit value in the entire process (step S106: Yes), the processing ends.

As described above, the design processing of the contact hole arrangement in the design device 30 of the second embodiment is terminated.

### Overview

It is difficult to optimize the arrangement of the contact holes having different reaching depths so that the layer thickness difference of the resist pattern is equal to or less than the upper limit value because various factors affect. Factors that affect the layer thickness difference of the resist pattern include a difference in a method of forming contact holes having different reaching depths, and a large number of variations in the arrangement of the contact holes. In addition, there are many design restrictions such as restriction on the arrangement order of the contact holes and necessity to secure a wiring path connected to the contact.

According to the design method in the design device 30 of the second embodiment, it is determined whether the layer thickness difference in the resist layer covering the plurality of holes having the predetermined arrangement satisfying the design restrictions is equal to or less than the predetermined upper limit value. As a result, when the arrangement of the contact holes is optimized, conditions of both the design restrictions and the layer thickness difference of the resist layer can be evaluated.

According to the design method in the design device 30 of the second embodiment, when the layer thickness difference of the resist layer described above exceeds the upper limit value, the arrangement of the plurality of holes is changed to another arrangement satisfying the design restrictions, and when the layer thickness difference in the resist layer covering these holes is equal to or less than the predetermined upper limit value, this arrangement is adopted. This makes it possible to achieve both the design restrictions and the layer thickness difference of the resist layer. Therefore, it is possible to obtain the arrangement of the contact holes capable of suppressing the variation in the layer thickness of the resist pattern on the plurality of contact holes having different reaching depths.

According to the design method in the design device 30 of the second embodiment, the calculation and determination of the layer thickness difference are repeatedly performed for different arrangements of the plurality of holes until the layer thickness difference of the resist layer becomes equal to or less than the upper limit value. As a result, it is possible to more reliably achieve both the design restrictions and the layer thickness difference of the resist layer.

According to the design method in the design device 30 of the second embodiment, the calculation and determination of the layer thickness difference of the resist layer for the holes in each stage of the plurality of steps are performed for each different arrangement of the plurality of holes. As a result, it is possible to achieve both the design restrictions and the layer thickness difference of the resist layer throughout the entire process.

According to the design method in the design device 30 of the second embodiment, arrangement newly generated from the initial arrangement is generated by including calculating the layer thickness difference of the resist layer in the initial arrangement for each predetermined region and changing the arrangement of the plurality of holes such that the layer thickness difference of the resist layer for each predetermined region is minimized. This makes it possible to suppress variations in the layer thickness of the resist pattern on the plurality of contact holes having different reaching depths.

### Modification

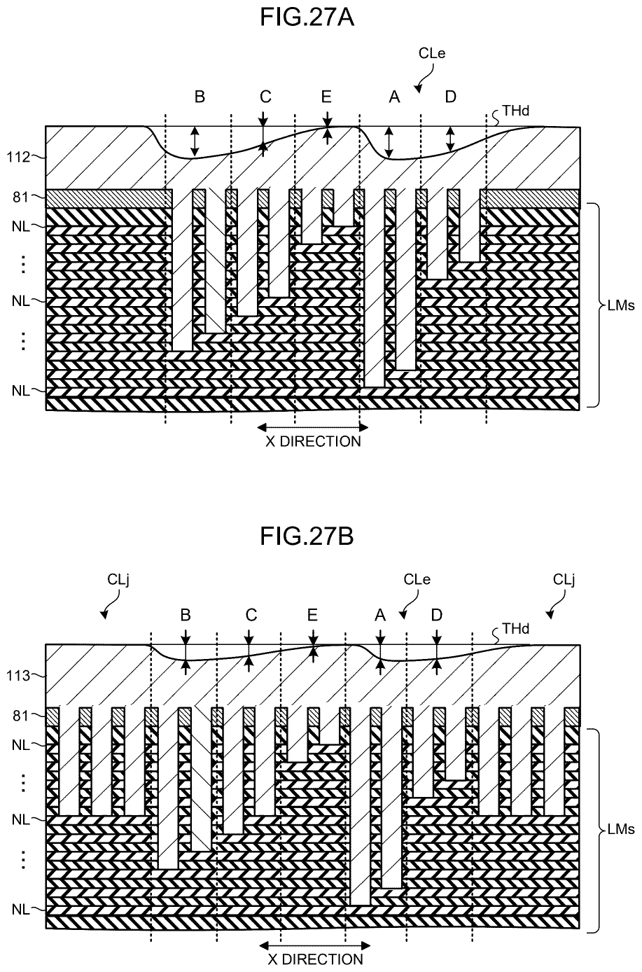

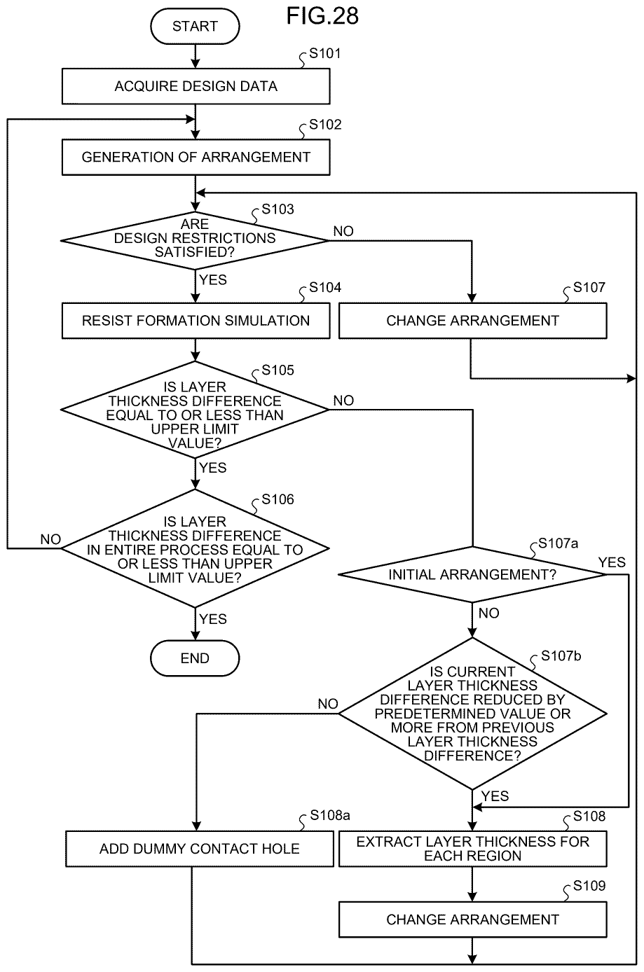

Next, a design device according to a modification of the second embodiment will be described with reference to FIGS. 27A to 28. The design device of the modification is different from that of the second embodiment in that it has a function of adding a dummy contact hole CLj under a predetermined condition.

FIGS. 27A and 27B are schematic diagrams illustrating an example of a design operation of arrangement of the contact holes CLe and CLj by the design device according to the modification of the second embodiment.

FIG. 27A is the same as FIG. 24B of the second embodiment described above. The design device of the modification determines whether to further add the dummy contact hole CLj to the arrangement of the predetermined contact holes CLe generated by the generation unit.

More specifically, the determination unit of the modification determines whether a layer thickness difference of the resist layer 112 formed on the contact hole CLe having the predetermined arrangement is reduced by a predetermined value or more as compared with the layer thickness difference of the resist layer in the contact hole CLe having the arrangement generated directly before the contact hole CLe. To summarize the examples of FIGS. 24A and 24B described above, the front of the resist layer 112 corresponds to the resist layer 111. Therefore, it is determined whether the layer thickness difference of the resist layer 112 is reduced by a predetermined amount or more with respect to the layer thickness difference of the resist layer 111.

When the layer thickness difference of the resist layer 112 is not much reduced as compared with the layer thickness difference of the resist layer 111, that is, when the reduction amount is less than a predetermined value, it means that the arrangement in FIG. 27A after the change is not much improved with respect to the immediately previous arrangement of the contact holes CLe in FIG. 24A. The reason why the layer thickness difference of the resist layer 112 is not sufficiently improved in the changed arrangement of the contact holes CLe is considered to mean that it is difficult to improve the layer thickness difference of the resist layer only by changing the arrangement order of the contact holes CLe.

As illustrated in FIG. 27B, in such a case, the generation unit of the modification does not generate a new arrangement by further changing the arrangement order of the contact holes CLe, but adds the dummy contact hole CLj to the arrangement in FIG. 27A. The additional position and the additional number of dummy contact holes CLj are determined based on the layer thickness difference of the resist layer in the arrangement of FIG. 27A.

This increases the possibility that improvement that cannot be obtained only by changing the arrangement order of the contact holes CLe is observed in the layer thickness difference of the resist layer 113.

FIG. 28 is a flowchart illustrating an example of a procedure of design processing of the contact hole arrangement by the design device according to the modification of the second embodiment.

As illustrated in FIG. 28, in the design device of the modification, in addition to the processing in steps S101 to S109 illustrated in FIG. 26 of the second embodiment described above, the processing in steps S107a, S107b, and S108a is performed. The processing in steps S107a and S107b is processing of determining whether to add a dummy contact hole, and the processing in step S108a is processing of adding a dummy contact hole.

That is, when the layer thickness difference of the resist layer exceeds the upper limit value in the predetermined arrangement of the contact holes (step S105: No), the determination unit of the modification determines whether the arrangement is the initial arrangement generated first in the processing (step S107a).

When the predetermined arrangement of the contact holes is not the initial arrangement but the arrangement generated by a change from the arrangement generated directly before (step S107a: No), the determination unit of the modification further determines whether the layer thickness difference of the resist layer is reduced by a predetermined value or more from the layer thickness difference in the immediately previous arrangement in the arrangement generated by the change (step S107b).

When the layer thickness difference of the resist layer in the arrangement generated by the change exhibits only a decrease amount smaller than the layer thickness difference in the immediately previous arrangement by less than the predetermined value (step S107b: No), it is considered that it is difficult to improve the layer thickness difference of the resist layer to the upper limit value or less even if the arrangement order of the contact holes in the arrangement is further changed.

Therefore, the generation unit of the modification does not change the arrangement order of the contact holes in the arrangement generated by the change, but adds a dummy contact hole to the arrangement generated by the change (step S108a).

The processing from step S103 is repeatedly performed for the arrangement in which the dummy contact hole is added.

On the other hand, when the predetermined arrangement of the contact holes is the initial arrangement (step S107a: Yes), there is no immediately previous arrangement to be compared. Therefore, the processing in step S107b is skipped.

In addition, even if the predetermined arrangement of the contact holes is an arrangement newly generated by the change (step S107a: No), in a case where the layer thickness difference of the resist layer in the arrangement is reduced by a predetermined value or more than the layer thickness difference in the immediately previous arrangement (step S107b: Yes), it is considered that there is room for improvement in the layer thickness difference of the resist layer to the upper limit value or less by further changing the arrangement order of the contact holes in the arrangement.

Therefore, the generation unit of the modification extracts a layer thickness difference of the resist layer for each region in the arrangement (step S108), and further changes the arrangement order of the contact holes based on the layer thickness difference (step S109).

The processing from step S103 is repeatedly performed for the arrangement obtained by further changing the arrangement order of the contact holes.

As described above, the design processing of the contact hole arrangement in the design device of the modification is terminated.

According to the design method in the design device of the modification, the predetermined arrangement of the contact holes is generated by including addition of the dummy contact hole adjacent to the arrangement region of the plurality of holes. This makes it possible to further suppress the variation in the layer thickness of the resist pattern on the plurality of contact holes having different reaching depths.

According to the design method in the design device of the modification, the dummy contact hole is added when the decrease amount of the layer thickness difference of the resist layer in the predetermined arrangement of the contact holes from the layer thickness difference in the immediately previous arrangement is less than the predetermined value. As a result, even in a situation in which it is difficult to obtain improvement by further changing the arrangement order of the contact holes, it is possible to obtain the arrangement of the contact holes capable of suppressing the variation in the layer thickness of the resist pattern on the plurality of contact holes having different reaching depths.

According to the design method in the design device of the modification, the predetermined arrangement of the contact holes is generated by calculating the layer thickness difference of the resist layer in the arrangement in which the layer thickness difference of the resist layer exceeds the upper limit value for each predetermined region when the decrease amount of the layer thickness difference of the resist layer in the predetermined arrangement of the contact holes from the layer thickness difference in the immediately previous arrangement is equal to or larger than the predetermined value, and changing the arrangement of the plurality of holes so as to minimize the layer thickness difference in each predetermined region.

According to the design method in the design device of the modification, other effects similar to those of the design method in the design device of the second embodiment described above are obtained.

### Other Modifications

In the second embodiment and the modification described above, the layer thickness difference of the resist layer formed on the contact hole having the predetermined arrangement is calculated by simulation. However, the evaluation method of the contact hole having the predetermined arrangement is not limited thereto. As an example, the layer thickness difference of the resist layer may be determined based on a volume density distribution of these contact holes or the like.

In the second embodiment and the modification described above, whether the arrangement of the contact holes generated by the generation unit satisfies various design restrictions is appropriately determined. However, the method of obtaining the arrangement satisfying the design restrictions is not limited thereto. As an example, a prohibition item may be provided in advance in generation of arrangement by the generation unit on the basis of various restrictions. In addition, the generation unit may be provided with a grouping function of individual contact holes, and the contact holes of each group may be handled as one group.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A design method of determining an arrangement of a plurality of holes having different reaching depths, the design method comprising:
calculating, in a case in which one or more restrictions related to design are present and in a case in which a resin layer covering the plurality of holes having a first arrangement satisfying the one or more restrictions is formed, a first layer thickness difference in the resin layer on the plurality of holes, the first layer thickness difference being generated by allowing a part of the resin layer to flow into the plurality of holes;
determining whether the first layer thickness difference is equal to or less than a predetermined upper limit value;
calculating, when the first layer thickness difference exceeds the upper limit value, a second layer thickness difference generated in the resin layer on the plurality of holes in a case in which the arrangement of the plurality of holes is changed to a second arrangement satisfying the one or more restrictions;
determining whether the second layer thickness difference is equal to or less than the upper limit value; and
adopting the second arrangement when the second layer thickness difference is equal to or less than the upper limit value.

2. The design method according to claim 1, wherein
calculation and determination of the layer thickness difference of the resin layer for different arrangements of the plurality of holes are repeatedly performed until the layer thickness difference becomes equal to or less than the upper limit value.

3. The design method according to claim 2, wherein
the plurality of holes are formed through a plurality of steps,
the respective reaching depths of the plurality of holes increase through the steps, and
calculation and determination of the layer thickness difference for the plurality of holes at respective stages of the plurality of steps are performed for each of the different arrangements of the plurality of holes.

4. The design method according to claim 1, wherein,
in the first arrangement,
the plurality of holes are regularly arranged according to the respective reaching depths, or
the plurality of holes are randomly arranged without being based on the respective reaching depths.

5. The design method according to claim 1, wherein
the second arrangement is generated by including:
calculating, for each predetermined region, the first layer thickness difference in the first arrangement; and
changing the arrangement of the plurality of holes such that the first layer thickness difference for the each predetermined region becomes minimized.

6. The design method according to claim 1, further comprising:
calculating, when the second layer thickness difference exceeds the upper limit value, a third layer thickness difference generated in the resin layer on the plurality of holes in a case in which the arrangement of the plurality of holes is changed to a third arrangement satisfying the one or more restrictions; and
determining whether the third layer thickness difference is equal to or less than the upper limit value.

7. The design method according to claim 6, wherein
the third arrangement is generated by including addition of a dummy hole in a region adjacent to an arrangement region of the plurality of holes.

8. The design method according to claim 7, wherein
the dummy hole is added when a reduction amount of the second layer thickness difference from the first layer thickness difference is less than a predetermined value.

9. The design method according to claim 8, wherein
the third arrangement is generated when the reduction amount of the second layer thickness difference from the first layer thickness difference is equal to or larger than the predetermined value by including:
calculating, for each predetermined region, the second layer thickness difference in the second arrangement; and
changing the arrangement of the plurality of holes such that the second layer thickness difference for each predetermined region becomes minimized.

10. The design method according to claim 1, wherein
the one or more restrictions include inserting a blank region in which none of the plurality of holes is arranged into an arrangement region of the plurality of holes.

11. The design method according to claim 1, wherein
a plurality of contacts are respectively formed from the plurality of holes, each of the contacts extending in a stacking direction of a stacked body obtained by allowing a plurality of conductive layers to be stacked apart from each other, each of the contacts being connected to any one of the plurality of conductive layers,
at least a part of the plurality of conductive layers is divided into one or more groups as a group of the conductive layers, and
the one or more restrictions include adjacently arranging the contacts connected to the conductive layers belonging to a same group.

12. The design method according to claim 11, wherein
the plurality of conductive layers are grouped for each function of at least a part of the conductive layers, or are grouped for each hierarchy in the stacked body.

13. The design method according to claim 11, wherein
the second arrangement is generated so as to comply with the one or more restrictions by collectively treating the group of conductive layers, or
a check is performed after generation of the second arrangement whether the second arrangement satisfies the one or more restrictions.

14. The design method according to claim 1, further comprising:
forming a plurality of contacts from the plurality of holes, each extending in a stacking direction of a stacked body obtained by allowing a plurality of conductive layers to be stacked apart from each other, each of the contacts being connected to any one of the plurality of conductive layers; and
respectively connecting wirings to the plurality of contacts, wherein
the one or more restrictions include securing wiring paths for the plurality of contacts.

15. A program for determination of an arrangement of a plurality of holes having different reaching depths, the program causing a computer to execute:
calculating, in a case in which one or more restrictions related to design are present and in a case in which a resin layer covering the plurality of holes having a first arrangement satisfying the one or more restrictions is formed, a first layer thickness difference in the resin layer on the plurality of holes, the first layer thickness difference being generated by allowing a part of the resin layer to flow into the plurality of holes;
determining whether the first layer thickness difference is equal to or less than a predetermined upper limit value;
calculating, when the first layer thickness difference exceeds the upper limit value, a second layer thickness difference generated in the resin layer on the plurality of holes in a case in which the arrangement of the plurality of holes is changed to a second arrangement satisfying the one or more restrictions;
determining whether the second layer thickness difference is equal to or less than the upper limit value; and
adopting the second arrangement when the second layer thickness difference is equal to or less than the upper limit value.

16. A semiconductor memory device comprising:
a stacked body obtained by allowing a plurality of conductive layers to be stacked apart from each other;
pillars extending in the stacked body in a stacking direction of the stacked body, wherein memory cells are formed at respective intersections between the pillars and at least a part of the plurality of conductive layers; and
a plurality of contacts extending in the stacked body in the stacking direction, the plurality of contacts having different reaching depths in the stacked body, wherein
the plurality of contacts are arranged side by side in a predetermined direction, and
the reaching depths are arranged so as to increase from both end portions toward a central portion in the predetermined direction.

17. The semiconductor memory device according to claim 16, wherein,
among the plurality of contacts, an average value of pitches between a plurality of first contacts respectively having the reaching depths equal to or larger than a first depth is greater than an average value of pitches between a plurality of second contacts respectively having the reaching depths less than the first depth.

18. The semiconductor memory device according to claim 17, wherein
the pitches between the plurality of first contacts are equal.

19. The semiconductor memory device according to claim 17, wherein
a first region in which the plurality of first contacts are arranged has a blank region in which none of the plurality of first contacts is arranged.

20. The semiconductor memory device according to claim 16, wherein
dummy contacts each having a reaching depth equal to or larger than a second depth are respectively arranged outside both end portions of an arrangement region of the plurality of contacts.
